(19) United States
(12) Patent Application Publication
(10) Pub. No.: US 2023/0171965 A1
(43) Pub. Date: Jun. 1, 2023

(54) SEMICONDUCTOR DEVICE AND DATA STORAGE SYSTEM INCLUDING THE SAME

(71) Applicant: SAMSUNG ELECTRONICS CO., LTD., Suwon-si (KR)

(72) Inventors: Seungmin LEE, Seoul (KR); Kwanyong KIM, Uijeongbu-si (KR); Jihwan YU, Suwon-si (KR)

(21) Appl. No.: 18/070,789

(22) Filed: Nov. 29, 2022

(30) Foreign Application Priority Data
Dec. 1, 2021 (KR) 10-2021-0170241

(51) Int. Cl. H10B 43/40; H10B 41/35; H01L 23/528; H10B 41/40; H10B 41/27; H10B 43/35; H10B 43/27

(52) U.S. Cl. CPC H01L 27/11573; H01L 27/11524; H01L 23/5283; H01L 27/11526; H01L 27/11556; H01L 27/1157; H01L 27/11582

(57) ABSTRACT

A semiconductor device including a stack structure including gate stack and dummy stack regions; a vertical memory structure penetrating through the gate stack region; and a first vertical dummy structure penetrating through a portion of the dummy stack region, wherein the gate stack region includes interlayer insulating and gate layers alternately and repeatedly stacked on each other, the dummy stack region includes dummy insulating and dummy horizontal layers alternately and repeatedly stacked on each other, at least one of the dummy horizontal layers and the gate layers include materials different from each other, an upper surface of the vertical memory structure is at a higher level than an upper surface of the first vertical dummy structure, and a lowermost dummy upper horizontal layer at a higher level than the first vertical dummy structure overlaps the first vertical dummy structure.

### CROSS-REFERENCE TO RELATED APPLICATION

This application claims the benefit under 35 USC 119(a) of Korean Patent Application No. 10-2021-0170241 filed on Dec. 1, 2021, in the Korean Intellectual Property Office, the entire disclosure of which is incorporated herein by reference for all purposes.

### BACKGROUND

### 1. Field

Embodiments relate to a semiconductor device and a data storage system including the same.

### 2. Description of the Related Art

An electronic system requiring data storage may use a semiconductor device which may store high-capacity data. Accordingly, a method for increasing data storage capacity of a semiconductor device has been considered.

### SUMMARY

The embodiments may be realized by providing a semiconductor device including a stack structure including a gate stack region and a dummy stack region; a vertical memory structure penetrating through the gate stack region in a vertical direction; and a first vertical dummy structure penetrating through at least a portion of the dummy stack region in the vertical direction, wherein the gate stack region includes interlayer insulating layers and gate layers alternately and repeatedly stacked on each other in the vertical direction, the dummy stack region includes dummy insulating layers and dummy horizontal layers alternately and repeatedly stacked on each other in the vertical direction, at least one of the dummy horizontal layers and at least one of the gate layers include materials different from each other, an upper surface of the vertical memory structure is at a higher level than an upper surface of the first vertical dummy structure, and a lowermost dummy horizontal layer of the dummy horizontal layers at a higher level than the first vertical dummy structure overlaps the first vertical dummy structure.

The embodiments may be realized by providing a semiconductor device including a lower structure including a memory cell region, a gate connection region, and a dummy region thereon; a stack structure on the lower structure on each of the memory cell region, the gate connection region, and the dummy region; a vertical memory structure penetrating through the stack structure on the memory cell region; a vertical dummy structure penetrating through the stack structure on the dummy region; and gate contact plugs on the gate connection region, wherein the stack structure includes a gate stack region in each of the memory cell region and the gate connection region, and a dummy stack region in the dummy region, the gate stack region includes a lower gate stack region and an upper gate stack region on the lower gate stack region, the dummy stack region includes a dummy lower stack region and a dummy upper stack region on the dummy lower stack region, the lower gate stack region includes lower interlayer insulating layers and lower gate layers alternately and repeatedly stacked on each other, the upper gate stack region includes upper interlayer insulating layers and upper gate layers alternately and repeatedly stacked on each other, the dummy lower stack region includes dummy lower insulating layers and dummy lower horizontal layers alternately stacked on each other, the dummy upper stack region includes dummy upper insulating layers and dummy upper horizontal layers alternately stacked on each other, the gate contact plugs are in contact with gate pads of the lower and upper gate layers in the gate connection region, the gate connection region is disposed in a first direction of the memory cell region, the dummy region is disposed in a second direction of the memory cell region, the second direction is perpendicular to the first direction, the vertical dummy structure is at a lower level than the dummy upper stack region, and a lowermost dummy upper horizontal layer of the dummy upper horizontal layers overlaps an upper surface of the vertical dummy structure in the dummy region.

The embodiments may be realized by providing a data storage system including a semiconductor device including an input/output pad; and a controller electrically connected to the semiconductor device through the input/output pad and controlling the semiconductor device, wherein the semiconductor device includes a lower structure including a memory cell region, a gate connection region, and a dummy region thereon on; a stack structure on the lower structure on each of the memory cell region, the gate connection region, and the dummy region; a vertical memory structure penetrating through the stack structure on the memory cell region; a vertical dummy structure penetrating through the stack structure on the dummy region; and gate contact plugs on the gate connection region, the stack structure includes a gate stack region on each of the memory cell region and the gate connection region and a dummy stack region on the dummy region, the gate stack region includes a lower gate stack region and an upper gate stack region on the lower gate stack region, the dummy stack region includes a dummy lower stack region and a dummy upper stack region on the dummy lower stack region, the lower gate stack region includes lower interlayer insulating layers and lower gate layers alternately and repeatedly stacked on each other, the upper gate stack region includes upper interlayer insulating layers and upper gate layers alternately and repeatedly stacked on each other, the dummy lower stack region includes dummy lower insulating layers and dummy lower horizontal layers alternately stacked on each other, the dummy upper stack region includes dummy upper insulating layers and dummy upper horizontal layers alternately stacked on each other, the gate contact plugs are in contact with gate pads of the lower and upper gate layers in the gate connection region, the gate connection region is disposed in a first direction of the memory cell region, the dummy region is disposed in a second direction of the memory cell region, the second direction is perpendicular to the first direction, the vertical dummy structure is at a lower level than the dummy upper stack region, and a lowermost dummy upper horizontal layer of the dummy upper horizontal layers overlaps an upper surface of the vertical dummy structure in the dummy region.

### BRIEF DESCRIPTION OF DRAWINGS

Features will be apparent to those of skill in the art by describing in detail exemplary embodiments with reference to the attached drawings in which:

FIG. 1 is a top view schematically illustrating a semiconductor device according to embodiments;

FIGS. 2A, 2B, 3A and 3B are views respectively schematically illustrating the semiconductor device according to embodiments;

FIGS. 4A and 4B are views respectively schematically illustrating a modified example of the semiconductor device according to embodiments;

FIGS. 5A, 5B and 6 are views respectively schematically illustrating a modified example of the semiconductor device according to embodiments;

FIGS. 7A and 7B are views respectively schematically illustrating a modified example of the semiconductor device according to embodiments;

FIGS. 8A and 8B are views respectively schematically illustrating a modified example of the semiconductor device according to embodiments;

FIGS. 9A and 9B are views respectively schematically illustrating a modified example of the semiconductor device according to embodiments;

FIG. 10 is a view schematically illustrating a modified example of the semiconductor device according to embodiments;

FIGS. 11A and 11B are views respectively schematically illustrating a modified example of a semiconductor device according to embodiments;

FIGS. 12A to 16B are views respectively schematically illustrating stages in a method of manufacturing a semiconductor device according to embodiments;

FIG. 17 is a view schematically illustrating a data storage system including a semiconductor device according to embodiments;

FIG. 18 is a view schematically illustrating the data storage system including a semiconductor device according to embodiments; and

FIG. 19 is a cross-sectional view schematically illustrating the data storage system including a semiconductor device according to embodiments.

### DETAILED DESCRIPTION

Terms such as “upper”, “middle” and “lower” may be replaced with other terms, e.g., “first,” “second” and “third,” etc. to be used to describe elements of the specification. Terms such as “first” and “second” may be used to describe various elements, but the elements are not limited by the terms, e.g., the terms are merely for differentiation and are not intended to imply or require sequential inclusion, and a “first element” may be referred to as a “second element.”

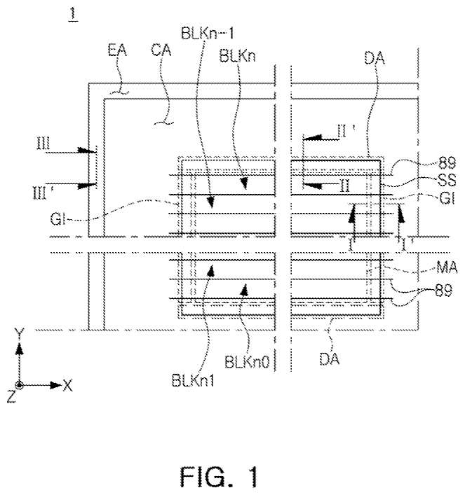

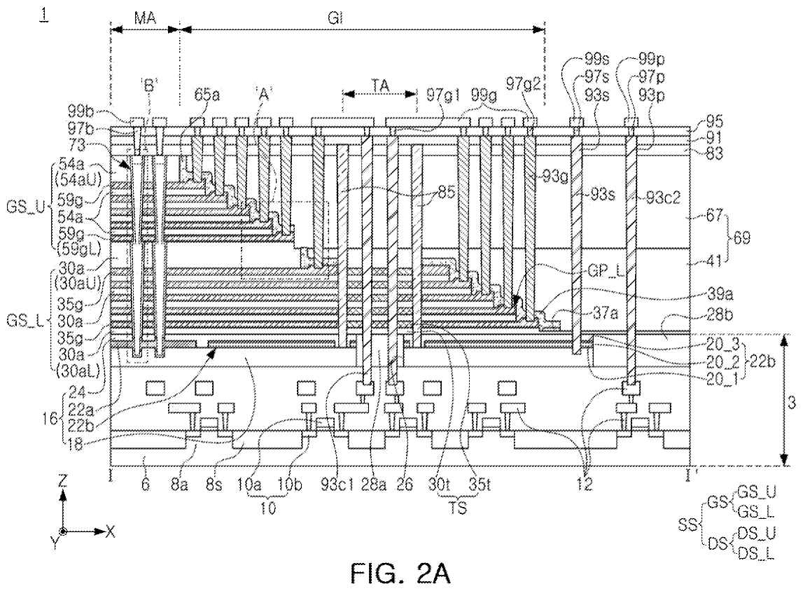

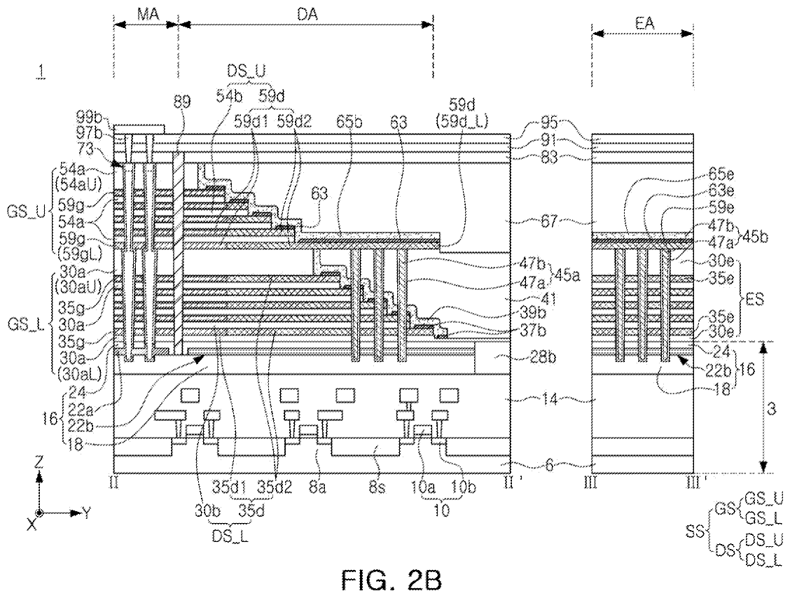

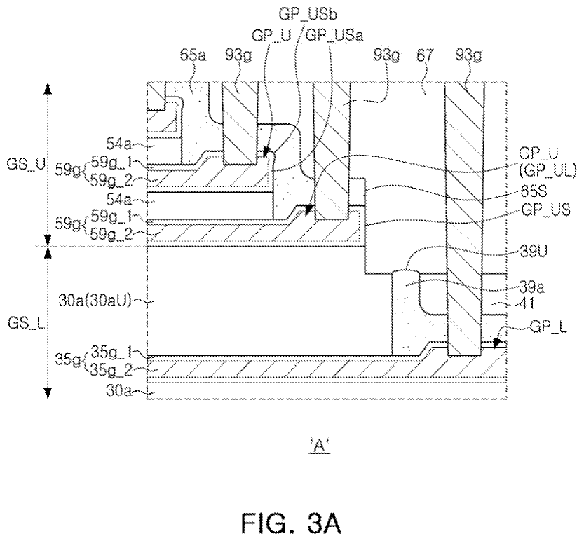

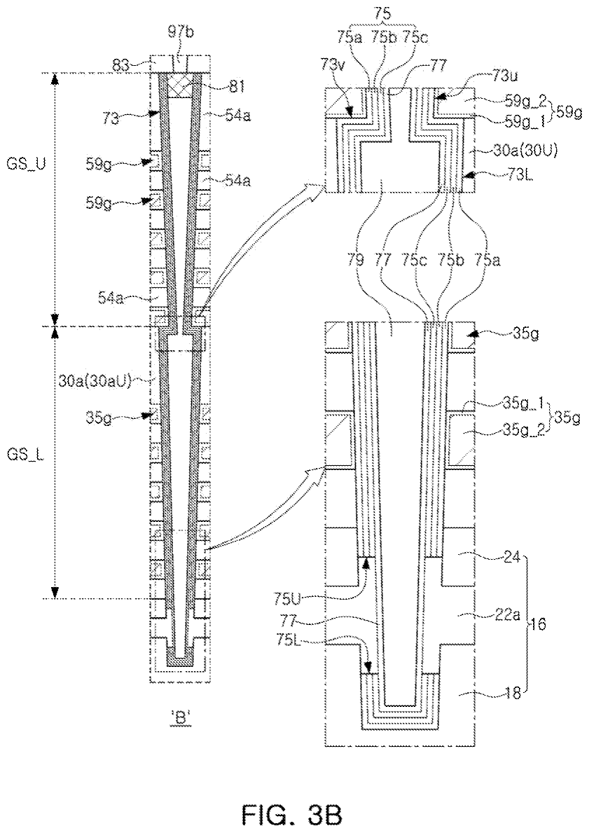

First, a semiconductor device according to embodiments is described with reference to FIGS. 1, 2A, 2B, 3A and 3B. FIG. 1 is a top view schematically illustrating a semiconductor device according to embodiments; and FIGS. 2A, 2B, 3A and 3B are views respectively schematically illustrating the semiconductor device according to embodiments. FIG. 2A is a cross-sectional view illustrating a region taken along line I-I′ in FIG. 1, FIG. 2B is a cross-sectional view illustrating regions taken along lines II-II′ and in FIG. 1, FIG. 3A is a partially enlarged view illustrating a region marked with ‘A’ in FIG. 2A, and FIG. 3B is a partially enlarged view illustrating a region marked with ‘B’ in FIG. 2A.

First, referring to FIG. 1, a semiconductor device 1 according to embodiments may include a chip region CA and an edge region EA surrounding the chip region CA.

The semiconductor device 1 may further include a memory cell region MA, a gate connection region GI, and a dummy region DA on the chip region CA.

The semiconductor device 1 may further include a stack structure SS on each of the memory cell region MA, the gate connection region GI, and the dummy region DA.

The gate connection region GI may be disposed in a first direction X of the memory cell region MA. The dummy region DA may be disposed in a second direction Y of the memory cell region MA. The second direction Y may be perpendicular to the first direction X.

The semiconductor device 1 may further include separation structures 89 each intersecting the memory cell region MA and the gate connection region GI, and defining n number of memory blocks BLK0, BLK1, . . . and BLKn. In an implementation, each of the memory blocks BLK0, BLK1, . . . and BLKn may be between a pair of adjacent separation structures of the separation structures 89. “n” may be a natural number greater than 2.

Each of the memory blocks BLK0, BLK1, . . . and BLKn may have a shape of a line or a rectangle extended in the first direction X.

Each of the separation structures 89 may be extended in the first direction X.

The separation structures 89 may intersect the stack structure SS in the memory cell region MA or the gate connection region GI.

Next, referring to FIGS. 2A, 2B, 3A and 3B together with FIG. 1, the semiconductor device 1 may further include a lower structure 3.

The lower structure 3 may include a substrate 6, a device isolation region 8s defining active regions 8a on the substrate 6, peripheral circuits 10 on the active regions 8a, a peripheral circuit wiring 12 on the peripheral circuits 10 and electrically connected to the peripheral circuits 10, and an insulating structure 14 covering the peripheral circuits 10 and the peripheral circuit wiring 12. The peripheral circuit 10 may include a transistor including a peripheral gate 10a and a peripheral source/drain 10b.

The substrate 6 may be a semiconductor substrate, e.g., a silicon substrate or a compound semiconductor substrate.

The lower structure 3 may further include a pattern structure 16. The pattern structure 16 may have an opening 26. The lower structure 3 may further include a gap fill insulating layer 28a filling the opening 26 and an intermediate insulating layer 28b disposed on an outer surface of the pattern structure 16.

The pattern structure 16 may include a lower layer 18, a first intermediate layer 22a and a second intermediate layer 22b on the lower layer 18 and spaced apart from each other, and an upper layer 24 above the lower layer 18 and covering the first and second intermediate layers 22a and 22b.

The pattern structure 16 may include at least one silicon layer. In an implementation, at least one of the lower layer 18, the first intermediate layer 22a, and the upper layer 24 may include a polysilicon layer of an N-type conductivity.

The second intermediate layer 22b may include a first layer 20_1, a second layer 20_2, and a third layer 20_3, which are sequentially stacked. The first and third layers 20_1 and 20_3 may include silicon oxide, and the second layer 20_2 may include silicon nitride or polysilicon.

The stack structure SS described with reference to FIG. 1 may be on the lower structure 3. The memory cell region MA, the gate connection region GI and the dummy region DA, described with reference to FIG. 1, may be on the lower structure 3.

The stack structure SS may include a gate stack region GS and a dummy stack region DS. The gate stack region GS may be on each of the memory cell region MA and the gate connection region GI, and the dummy stack region DS may be on the dummy region DA.

The gate stack region GS may include a lower gate stack region GS_L and an upper gate stack region GS_U on the lower gate stack region GS_L. The dummy stack region DS may include a dummy lower stack region DS_L and an dummy upper stack region DS_U on the dummy lower stack region DS_L.

The lower gate stack region GS_L may include lower interlayer insulating layers 30a and lower gate layers 35g alternately and repeatedly stacked on each other. The upper gate stack region GS_U may include upper interlayer insulating layers 54a and upper gate layers 59g alternately and repeatedly stacked on each other. The dummy lower stack region DS_L may include dummy lower insulating layers 30b and dummy lower horizontal layers 35d alternately and repeatedly stacked on each other. The dummy upper stack region DS_U may include dummy upper insulating layers 54b and dummy upper horizontal layers 59d alternately and repeatedly stacked on each other.

In an implementation, each of the lower gate layer 35g may include a first gate layer 35g_1 and a second gate layer 35g_2. The first gate layer 35g_1 may cover the upper and lower surfaces of the second gate layer 35g_2, and may partially cover a side surface of the second gate layer 35g_2. Each of the upper gate layers 59g may include a first gate layer 59g_1 and a second gate layer 59g_2. The first gate layer 59g_1 may cover the upper and lower surfaces of the second gate layer 59g_2, and may partially cover a side surface of the second gate layer 59g_2.

In an implementation, the first gate layer 35g_1 or 59g_1 may include an insulating material, e.g., a high dielectric such as aluminum oxide, and the second gate layer 35g_2 or 59g_2 may include a conductive material, e.g., doped polysilicon, tungsten (W), ruthenium (Ru), molybdenum (Mo), nickel (Ni), nickel silicide (NiSi), cobalt (Co), cobalt silicide (CoSi), titanium (Ti), tantalum (Ta), titanium silicide (TiSi), tantalum silicide (TaSi), titanium nitride (TiN), tantalum nitride (TaN), or tungsten nitride (WN). As used herein, the term “or” is not an exclusive term, e.g., “A or B” would include A, B, or A and B.

In an implementation, the first gate layer 35g_1 or 59g_1 may include a first conductive material such as titanium nitride (TiN), tantalum nitride (TaN) or tungsten nitride (WN), and the second gate layer 35g_2 or 59g_2 may include a second conductive material different from the first conductive material, e.g., tungsten (W), ruthenium (Ru), molybdenum (Mo), nickel (Ni), nickel silicide (NiSi), cobalt (Co), cobalt silicide (CoSi), titanium (Ti), tantalum (Ta), titanium silicide (TiSi) or tantalum silicide (TaSi).

In an implementation, the lower or upper gate layer 35g or 59g may be formed of one conductive material layer, e.g., a conductive material layer including doped polysilicon, tungsten (W), ruthenium (Ru), molybdenum (Mo), nickel (Ni), nickel silicide (NiSi), cobalt (Co), cobalt silicide (CoSi), titanium (Ti), tantalum (Ta), titanium silicide (TiSi), tantalum silicide (TaSi), titanium nitride (TiN), tantalum nitride (TaN) or tungsten nitride (WN).

In an implementation, a portion formed of the conductive material layer in the lower or upper gate layer 35g or 59g may be referred to as a gate electrode.

The lower gate layers 35g may be stacked on each other while being spaced apart from each other in a vertical direction Z on the memory cell region MA, and may extend onto the gate connection region GI. On the gate connection region GI, the lower gate layers 35g may have lower gate pads GP_L each having an increased thickness. In an implementation, a thickness of at least one of the lower gate pads GP_L on the gate connection region GI may be greater than a thickness of at least one of the lower gate layers 35g in the memory cell region MA. On the gate connection region GI, the lower gate pads GP_L may be arranged in a step shape.

The upper gate layers 59g may be stacked on each other while being spaced apart from each other in the vertical direction Z on the memory cell region MA, and may extend onto the gate connection region GI. On the gate connection region GI, the upper gate layers 59g may have upper gate pads GP_U each having an increased thickness. In an implementation, a thickness of at least one of the upper gate pads GP_U on the gate connection region GI may be greater than a thickness of at least one of the upper gate layers 59g on the memory cell region MA. On the gate connection region GI, the upper gate pads GP_U may be arranged in the step shape.

Among the lower interlayer insulating layers 30a and the lower gate layers 35g, a lowermost layer may be a lowermost lower interlayer insulating layer 30aL, and an uppermost layer may be an uppermost lower interlayer insulating layer 30aU.

Among the upper interlayer insulating layers 54a and the upper gate layers 59g, a lowermost layer may be a lowermost upper gate layer 59g, and an uppermost layer may be an uppermost upper interlayer insulating layer 54aU.

The dummy lower insulating layers 30b and the dummy lower horizontal layers 35d may respectively be at substantially the same level as the lower interlayer insulating layers 30a and the lower gate layers 35g, and may have an step-shaped end.

The dummy upper insulating layers 54b and the dummy upper horizontal layers 59d may be at substantially the same level as the upper interlayer insulating layers 54a and the upper gate layers 59g, and may have the step-shaped end.

The dummy lower insulating layers 30b and the lower interlayer insulating layers 30a may be formed of the same material as each other, e.g., silicon oxide.

The dummy upper insulating layers 54b and the upper interlayer insulating layers 54a may be formed of the same material as each other, e.g., silicon oxide.

In an implementation, each of the dummy lower horizontal layers 35d may include a first horizontal portion 35d1 and a second horizontal portion 35d2. At least a portion of the dummy lower horizontal layers 35d may be formed of the same material as at least a portion of the lower gate layers 35g. The first horizontal portion 35d1 may be formed of the same material as the lower gate layers 35g. At least a portion of the dummy lower horizontal layers 35d may be formed of a material different from a material of at least a portion of the lower gate layers 35g. The second horizontal portion 35d2 may be formed of a material different from that of the first horizontal portion 35d1. In an implementation, the first horizontal portion 35d1 may include the conductive material, and the second horizontal portion 35d2 may include an insulating material, e.g., silicon nitride, at the same level as the first horizontal portion 35d1.

In an implementation, the dummy lower horizontal layers 35d and the lower gate layers 35g may be formed of the same material as each other. In an implementation, each of the dummy lower horizontal layers 35d may be formed of one conductive material layer.

In an implementation, at least one of the dummy upper horizontal layers 59d may include a first horizontal portion 59d1 and a second horizontal portion 59d2. At least a portion of the dummy upper horizontal layers 59d may be formed of the same material as at least a portion of the upper gate layers 59g. The first horizontal portion 35d1 may be formed of the same material as the upper gate layers 59g. At least a portion of the dummy upper horizontal layers 59d may be formed of a material different from a material of at least a portion of the upper gate layers 59g. The second horizontal portion 59d2 may be formed of a material different from that of the first horizontal portion 59d1. In an implementation, the first horizontal portion 59d1 may include a conductive material, and the second horizontal portion 59d2 may include an insulating material, e.g., silicon nitride, at the same level as the first horizontal portion 59d1.

In an implementation, the dummy upper horizontal layers 59d and the upper gate layers 59g may be formed of the same material as each other. In an implementation, each of the dummy upper horizontal layers 59d may be formed of one conductive material layer.

The semiconductor device 1 may further include a first lower insulating liner 39a covering the lower gate stack region GS_L and a first upper insulating liner 65a covering the upper gate stack region GS_U, in the gate connection region GI.

The semiconductor device 1 may further include a second lower insulating liner 39b covering the dummy lower stack region DS_L, and a second upper insulating liner 65b covering the dummy upper stack region DS_U, in the dummy region DA.

The first lower insulating liner 39a, the first upper insulating liner 65a, the second lower insulating liner 39b, and the second upper insulating liner 65b may include the same material as each other, e.g., a high dielectric such as aluminum oxide.

The semiconductor device 1 may further include a lower capping insulating layer 41 on the lower structure 3 and covering the lower gate stack region GS_L and the dummy lower stack region DS_L, and an upper capping insulating layer 67 on the lower capping insulating layer 41 and covering the upper gate stack region GS_U and the dummy upper stack region DS_U. The lower and upper capping insulating layers 41 and 67 may each be formed of an insulating material, e.g., silicon oxide or the like. The lower and upper capping insulating layers 41 and 67 may be included in a capping structure 69.

The semiconductor device 1 may further include a first lower additional insulating layer 37a. The first lower additional insulating layer 37a may be adjacent to an end of the lowermost lower gate layer of the lower gate layers 35g, and may be disposed between the lowermost lower interlayer insulating layer 30aL among the lower interlayer insulating layers 30a and the first lower insulating liner 39a. The first lower additional insulating layer 37a may be formed of a material different from the lower interlayer insulating layers 30a, e.g., silicon nitride.

The semiconductor device 1 may further include second lower additional insulating layers 37b and upper additional insulating layers 63.

The second lower additional insulating layer 37b may be in a region adjacent to the end of the lowermost dummy lower horizontal layer among the dummy lower horizontal layers 35d, or may be on an upper surface of a stepped end of the second horizontal portion 35d2 among the dummy lower horizontal layers 35d. The second lower additional insulating layer 37b may be covered by the second lower insulating liner 39b.

An upper additional insulating layer 63 may be on an upper surface of a lowermost dummy upper horizontal layer 59d_L not overlapping another dummy upper horizontal layer of the dummy upper horizontal layers 59d or an upper surface of each of second horizontal portions 59d2 arranged in a step shape among the dummy upper horizontal layers 59d. An upper additional insulating layer 63 may be covered by the second upper insulating liner 65b.

The semiconductor device 1 may further include an edge stack structure ES on the lower structure 3 on the edge region EA. The edge stack structure ES may include edge insulating layers 30e and edge dummy horizontal layers 35e alternately and repeatedly stacked on each other. The edge insulating layer 30e and the edge dummy horizontal layer 35e may respectively be at substantially the same level as the lower interlayer insulating layer 30a and the lower gate layer 35g. The edge insulating layer 30e may be formed of the same material as the lower interlayer insulating layer 30a, and the edge dummy horizontal layer 35e may be formed of the same material as the second horizontal portion 35d2 of the dummy lower horizontal layer 35d.

The semiconductor device 1 may further include a first vertical dummy structure 45a penetrating through the dummy lower stack region DS_L on the dummy region DA. In the dummy region DA, the stack structure SS may have the step shape, and the first vertical dummy structure 45a may penetrate through a portion of the stack structure SS, having the step shape, e.g., a portion of the dummy lower stack region DS_L, having the step shape.

The semiconductor device 1 may further include a second vertical dummy structure 45b penetrating through the edge stack structure ES on the edge region EA.

Each of the first and second vertical dummy structures 45a and 45b may include a dummy pattern 47b and a dummy liner 47a covering the side and bottom surfaces of the dummy pattern 47b. In an implementation, the dummy pattern 47b may be formed of a metal material, e.g., tungsten (W), and the dummy liner 47a may be a barrier layer formed of, e.g., titanium nitride (TiN). In an implementation, the dummy pattern 47b and the dummy liner 47a may be formed of a material different from the above-mentioned material.

The lowermost dummy upper horizontal layer 59d_L of the dummy upper horizontal layers 59d at a higher level than the first vertical dummy structure 45a among the dummy horizontal layers 35d and 59d may overlap the first vertical dummy structure 45a, and at least a plurality of the rest dummy upper horizontal layers 59d may not overlap the first vertical dummy structure 45a.

In an implementation, the lowermost dummy upper horizontal layer 59d_L may be in contact with an upper surface of the first vertical dummy structure 45a. A lower surface of the second horizontal portion 59d2 of the lowermost dummy upper horizontal layer 59d_L may be in contact with the upper surface of the first vertical dummy structure 45a. A material of the second horizontal portion 59d2 of the lowermost dummy upper horizontal layer 59d_L may be in contact with the upper surface of the first vertical dummy structure 45a.

The semiconductor device 1 may further include an edge horizontal layer 59e covering the second vertical dummy structure 45b. The edge horizontal layer 59e may be disposed at the same level as a lowermost dummy upper horizontal layer 59d_L.

The edge horizontal layer 59e may be formed of the same material as a portion of the lowermost dummy upper horizontal layer 59d_L, e.g., the second horizontal portion 59d2. An upper surface of the second vertical dummy structure 45b may be in contact with the edge horizontal layer 59e.

The semiconductor device 1 may further include an edge additional insulating layer 63e in contact with an upper surface of the edge horizontal layer 59e, and an edge insulating liner 65e in contact with an upper surface of the edge additional insulating layer 63e. The edge additional insulating layer 63e may be formed of the same material as the upper additional insulating layer 63, and the edge insulating liner 65e may be formed of the same material as the second upper insulating liner 65b.

The upper capping insulating layer 67 may cover the first and second upper insulating liners 65a and 65b and the edge insulating liner 65e.

The semiconductor device 1 may further include a vertical memory structure 73 penetrating through the stack structure SS in the memory cell region MA.

The semiconductor device 1 may further include a through region TA on the gate connection region GI. The through region TA may include a through-insulating structure TS including insulating layers 30t and horizontal layers 35t alternately stacked on each other. The through-insulating structure TS may vertically overlap the gap fill insulating layer 28a. In an implementation, the through-insulating structure TS may be positioned as illustrated in FIG. 2A, or may be disposed in any of various shapes or positions.

In an implementation, the lower gate layers 35g of the lower gate stack region GS_L may not be completely isolated by the through-insulating structure TS. In an implementation, the through-insulating structure TS may penetrate through a portion of the lower gate stack region GS_L. Portions of any one lower gate layer of the lower gate layers 35g, on both sides of the through-insulating structure TS, may thus be electrically connected to each other.

The semiconductor device 1 may further include the vertical memory structure 73 penetrating through the stack structure SS on the memory cell region MA.

The semiconductor device 1 may further include a first upper insulating layer 83, a second upper insulating layer 91 and a third upper insulating layer 95 which are sequentially stacked on the stack structure SS and the second capping insulating layer 67.

The semiconductor device 1 may further include a dam structure 85 penetrating through the stack structure SS and surrounding the through-stack region TA.

The separation structures 89 may penetrate through the first upper insulating layer 83 and the stack structure SS, and may be extended into the pattern structure 16.

In an implementation, the separation structures 89 may be formed of an insulating material.

In an implementation, each of the separation structures 89 may include a conductive pattern and an insulating spacer covering a side surface of the conductive pattern. In an implementation, the conductive pattern may be in contact with the lower layer 18 of the pattern structure 16.

The semiconductor device 1 may further include gate contact plugs 93g electrically connected to the lower and upper gate layers 35g and 59g on the gate connection region GI. In an implementation, the gate contact plugs 93g may be on and in contact with the lower and upper gate pads GP_L and GP_U. The gate contact plugs 93g may penetrate through the first and second upper insulating layers 83 and 91 and the capping structure 69, may penetrate through the insulating liners 39a and 65a covering the lower and upper gate pads GP_L and GP_U, and may be in contact with the lower and upper gate pads GP_L and GP_U.

The semiconductor device 1 may further include a source contact plug 93s penetrating through the first and second upper insulating layers 83 and 91 and the capping structure 69 and in contact with the lower layer 18 of the pattern structure 16.

The semiconductor device 1 may further include a first through-contact plug 93c1 penetrating through the first and second upper insulating layers 83 and 91, the capping structure 69, the through-stack structure TS, and the gap fill insulating layer 28a, and extended down to be electrically connected with the peripheral circuit wiring 12, and a second through-contact plug 93c2 penetrating through the first and second upper insulating layers 83 and 91, the capping structure 69, and the intermediate insulating layer 28b, and extended down to be electrically connected with the peripheral circuit wiring 12.

The semiconductor device 1 may further include a bit line contact plug 97b on the vertical memory structure 73, a first gate connection plug 97g1 on the first through-contact plug 93c1, a second gate connection plugs 97g2 on the gate contact plugs 93g, a source connection plug 97s on the source contact plug 93s, and a peripheral connection plug 97p on the second through-contact plug 93c2.

The semiconductor device 1 may further include a bit line 99b, a gate connection wiring 99g, a source connection wiring 99s and a peripheral connection wiring 99p on the third upper insulating layer 95. The bit line 99b may be electrically connected with the vertical memory structure 73 through the bit line contact plug 97b. The gate connection wiring 99g may be electrically connected to the first and second gate connection plugs 97g1 and 97g2. The source connection wiring 99s may be electrically connected with the source connection plug 97s, and the peripheral connection wiring 99p may be electrically connected with the peripheral connection plug 97p.

Next, the description describes a cross-sectional structure of the region marked with ‘A’ in FIG. 2A, focusing on FIG. 3A.

Mainly referring FIG. 3A among FIGS. 1 to 3B, the lowermost upper gate pad GP_UL of the upper gate pads GP_U may have a side surface having a different shape from a side surface of another upper gate pad GP_U. In an implementation, a side surface GP_US of the lowermost upper gate pad GP_UL may have a constant inclination, e.g., a vertical inclination, and a side surface of the other upper gate pad GP_U may include a first side portion GP_USa and a second side portion GP_USb on the first side portion GP_USa.

The side surface of the other upper gate pad GP_U may include the first side portion GP_USa having substantially the same inclination as the side surface GP_US of the lowermost upper gate pad GP_UL, and the second side portion GP_USb not vertically aligned with the first side portion GP_USa. In an implementation, the second side portion GP_USb may have a protruding shape compared to that of the first side portion GP_USa. The first side portion GP_USa may be greater (e.g., larger or taller) than the second side portion GP_USb.

An outer side surface 65S of a lower end of the first upper insulating liner 65a may be vertically aligned with the side surface GP_US of the lowermost upper gate pad GP_UL.

The first lower insulating liner 39a may cover a side surface of the uppermost lower interlayer insulating layer 30aU of the lower interlayer insulating layers 30a.

An upper end portion (39U in FIG. 3A) of the first lower insulating liner 39a may not vertically overlap the upper gate layers 59g.

Next, the description describes a cross-sectional structure of the region marked with ‘B’ in FIG. 2A, focusing on FIG. 3B.

Mainly referring FIG. 3B among FIGS. 1 to 3B, the vertical memory structure 73 may include an insulating core region 79, a channel layer 77 covering the side and bottom surfaces of the insulating core region 79, a data storage structure 75 covering the outer side and bottom surfaces of the channel layer 77, and a pad pattern 81 on the insulating core region 79 and in contact with the channel layer 77.

The data storage structure 75 may include a first dielectric layer 75a, a second dielectric layer 75c, and a data storage layer 75b between the first dielectric layer 75a and the second dielectric layer 75c. The second dielectric layer 75c may be in contact with the channel layer 77.

The first dielectric layer 75a may include silicon oxide or a high-k dielectric. The second dielectric layer 75c may include silicon oxide or silicon oxide doped with impurities. The data storage layer 75b may include a material capable of trapping a charge and storing data, e.g., silicon nitride.

The data storage layer 75b of the vertical memory structure 73 may include a region in which the semiconductor device stores the data, such as a flash memory or a variable resistance memory.

The pad pattern 81 may include, e.g., doped polysilicon, a metal nitride (e.g., titanium nitride (TiN)), a (non-compounded) metal (e.g., tungsten (W)), or a metal-semiconductor compound (e.g., titanium silicide (TiSi)).

A material of the channel layer 77 may be different from the material of the dummy liner 47a. In an implementation, the channel layer 77 may be formed of a semiconductor layer. The channel layer 77 may be formed of a silicon layer. The dummy liner 47a may be formed of a metal nitride such as titanium nitride (TiN).

A material of the insulating core region 79 may be different from the material of the dummy pattern 47b. In an implementation, the insulating core region 79 may include silicon oxide, and the dummy pattern 47b may include the metal such as tungsten.

The first intermediate layer 22a may penetrate through the data storage structure 75 and be in contact with the channel layer 77. In an implementation, the data storage structure 75 may be divided into a lower portion 75L and an upper portion 75U by the first intermediate layer 22a.

The vertical memory structure 73 may include a lower vertical portion 73L penetrating through the lower gate stack region GS_L, an upper vertical portion 73u penetrating through the upper gate stack region GS_U, and a slope change portion 73v formed by a difference between an inclination of the lower vertical portion 73L and an inclination of the upper vertical portion 73u.

An upper side surface of the lower vertical portion 73L and a lower side surface of the upper vertical portion 73u may not be vertically aligned with each other. In an implementation, the slope change portion 73v may be referred to as a bent portion or an inclination change portion.

The slope change portion 73v may be in contact with the lowermost upper gate layer 59g of the upper gate layers 59g.

Hereinafter, the description mainly describes a component which may be modified or a component which may be replaced among the components of the semiconductor device 1 according to embodiments.

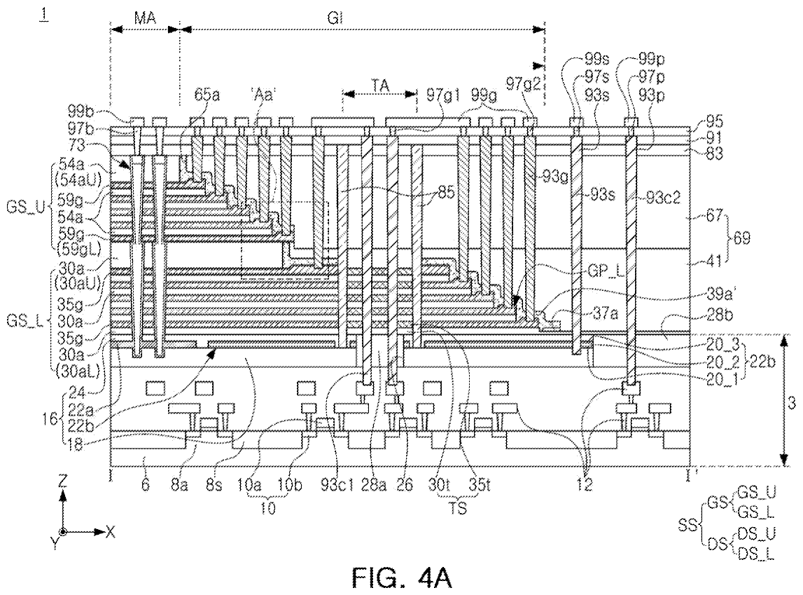

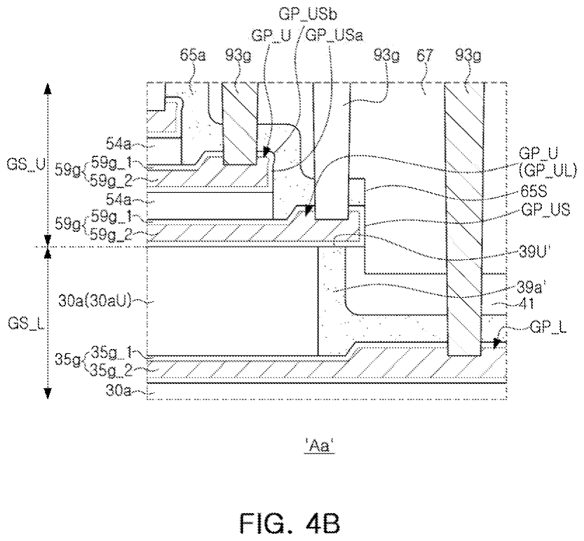

First, with reference to FIGS. 4A and 4B, the description mainly describes a component modified from that of the semiconductor device 1 according to embodiments. FIGS. 4A and 4B are views respectively schematically illustrating a modified example of the semiconductor device according to embodiments. FIG. 4A is a cross-sectional view illustrating the region taken along line I-I′ in FIG. 1, and FIG. 4B is a partially enlarged view of a region marked with ‘Aa’ in FIG. 4A.

Referring to FIGS. 4A and 4B, the first lower insulating liner 39a (in FIGS. 2A and 3A) having the upper end portion 39U (in FIG. 3A) which does not vertically overlap the upper gate layer 59g (in FIG. 3A) may be modified into a first lower insulating liner 39a′ having an upper end portion 39U′ (in FIG. 4B) which vertically overlaps at least one of the upper gate layers 59g (in FIGS. 4A and 4B), as illustrated in FIGS. 4A and 4B.

The upper end portion 39U′ of the first lower insulating liner 39a′ may be in contact with the lowermost upper gate layer 59g.

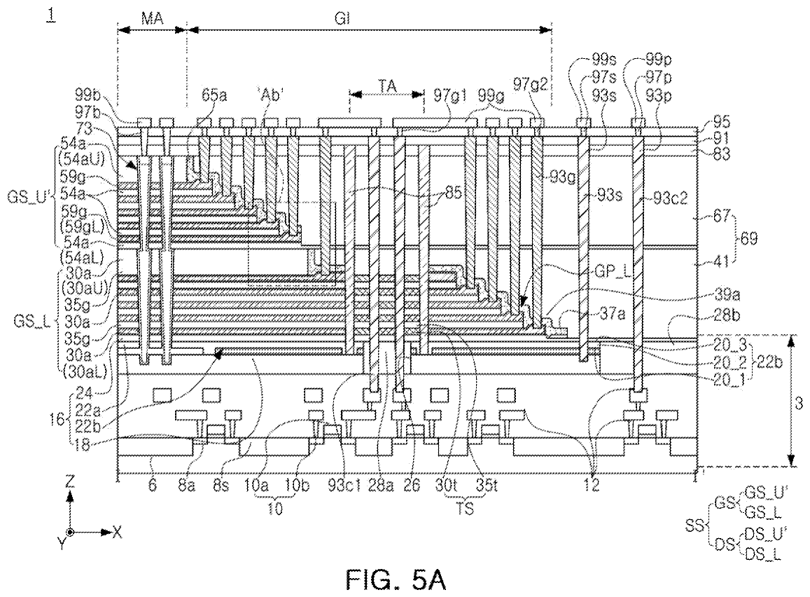

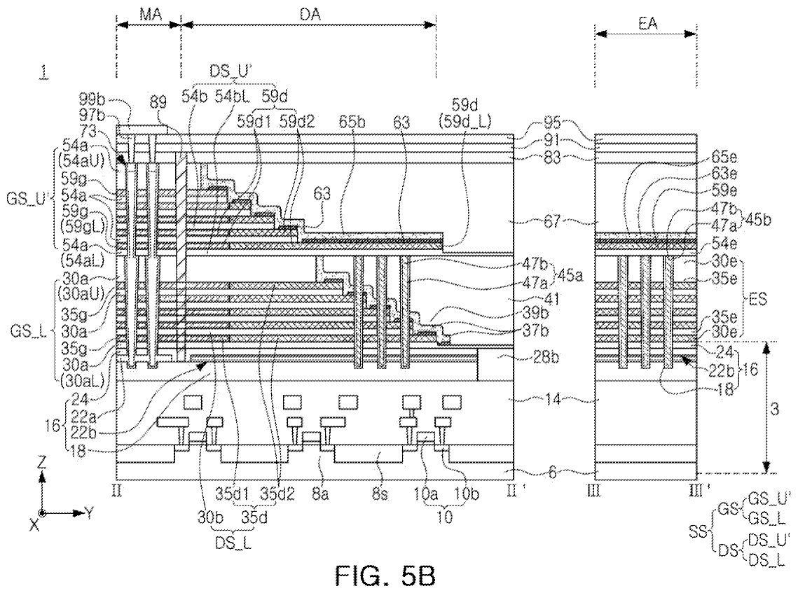

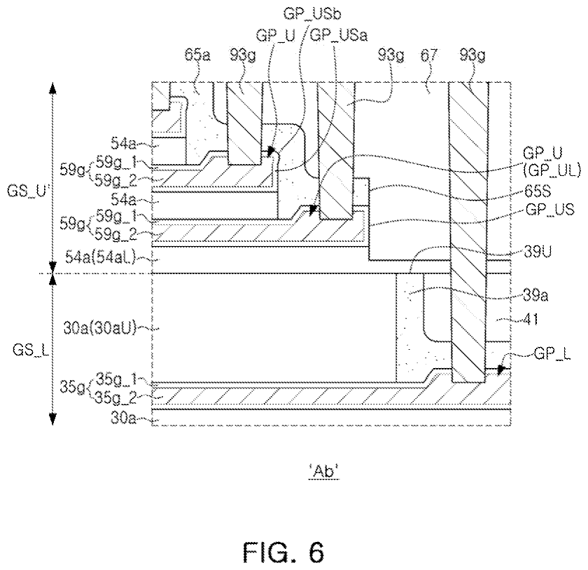

Next, with reference to FIGS. 5A, 5B and 6, the description mainly describes a component modified from that of the semiconductor device 1 according to embodiments. FIGS. 5A, 5B and 6 are views respectively schematically illustrating a modified example of the semiconductor device according to embodiments. FIG. 5A is a cross-sectional view illustrating the region taken along line I-I′ in FIG. 1, FIG. 5B is a cross-sectional view illustrating the regions taken along lines II-II′ and in FIG. 1, and FIG. 6 is a partially enlarged view of a region marked with ‘Ab’ in FIG. 5A.

Referring to FIGS. 5A, 5B and 6, the upper gate stack region GS_U described with reference to FIGS. 2A to 3B may be modified into an upper gate stack region GS_U′ as illustrated in FIGS. 5A and 5B, and the dummy upper stack region DS_U described with reference to FIG. 2B may be modified into an dummy upper stack region DS_U′ as illustrated in FIG. 5B.

The upper gate stack region GS_U′ may include the upper interlayer insulating layers 54a and the upper gate layers 59g alternately and repeatedly stacked on each other, and a lowermost layer among the upper interlayer insulating layers 54a and the upper gate layers 59g may be a lowermost upper interlayer insulating layer 54aL.

The lowermost upper interlayer insulating layer 54aL may cover the upper end portion 39U of the first lower insulating liner 39a.

The dummy upper stack region DS_U′ may include the dummy upper insulating layers 54b and the dummy upper horizontal layers 59d, alternately stacked on each other, and a lowermost layer among the dummy upper insulating layers 54b and the dummy upper horizontal layers 59d may be a lowermost dummy upper insulating layer 54bL.

The lowermost dummy upper insulating layer 54bL may be in contact with the upper surface of the first vertical dummy structure 45a while covering the upper surface of the first vertical dummy structure 45a.

The lowermost dummy upper insulating layer 54bL may cover an upper end portion of the second lower insulating liner 39b.

The semiconductor device 1 may further include an edge insulating layer 54e at substantially the same level as the lowermost upper interlayer insulating layer 54aL and the lowermost dummy upper insulating layer 54bL, covering the upper surface of the second vertical dummy structure 45b, and in contact with a lower surface of the edge horizontal layer 59e. The lowermost upper interlayer insulating layer 54aL, the lowermost dummy upper insulating layer 54bL, and the edge insulating layer 54e may be formed of the same material as each other, e.g., silicon oxide.

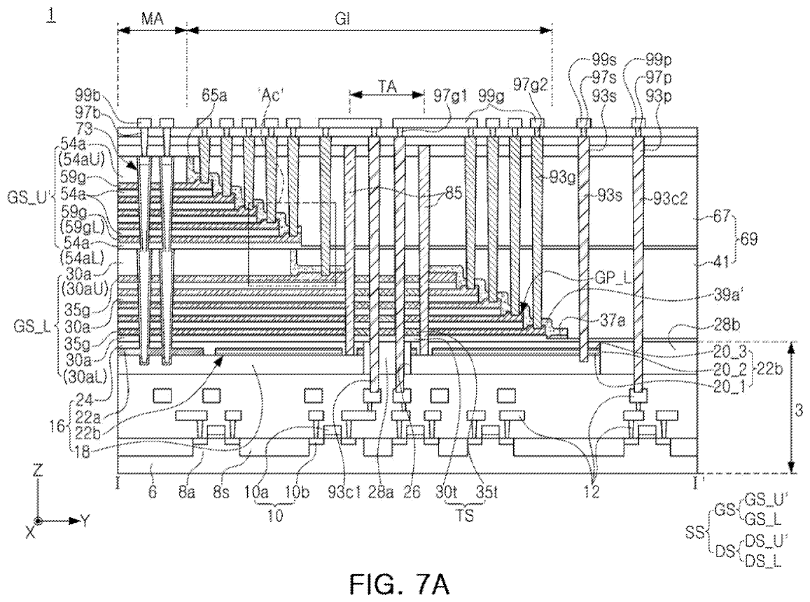

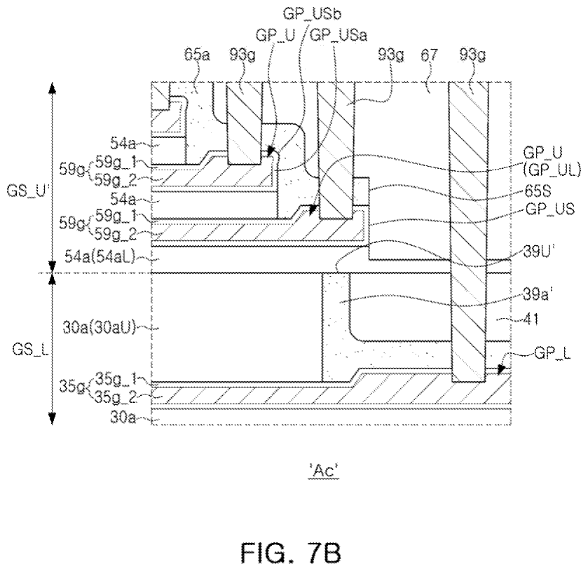

Next, with reference to FIGS. 7A and 7B, the description mainly describes a component modified from that of the semiconductor device 1 according to embodiments. FIGS. 7A and 7B are views respectively schematically illustrating a modified example of the semiconductor device according to embodiments. FIG. 7A is the cross-sectional view illustrating the region taken along line I-I′ in FIG. 1, and FIG. 7B is a partially enlarged view of a region marked with ‘Ac’ in FIG. 7A.

Referring to FIGS. 7A and 7B, the upper gate stack region GS_U described with reference to FIGS. 2A to 3B may be modified to the upper gate stack region GS_U′ as illustrated in FIGS. 5A and 5B.

The first lower insulating liner 39a (in FIGS. 2A and 3A) having the upper end portion 39U (in FIG. 3A) which does not vertically overlap the upper gate layer 59g (in FIG. 3A) may be modified into the first lower insulating liner 39a′ having the upper end portion 39U′ (in FIG. 7B) which vertically overlaps at least one of the upper gate layers 59g (in FIGS. 7A and 7B), as illustrated in FIGS. 7A and 7B.

The upper end portion 39U′ of the first lower insulating liner 39a′ may be in contact with the lowermost upper interlayer insulating layer 54aL as described with reference to FIGS. 5A, 5B and 6.

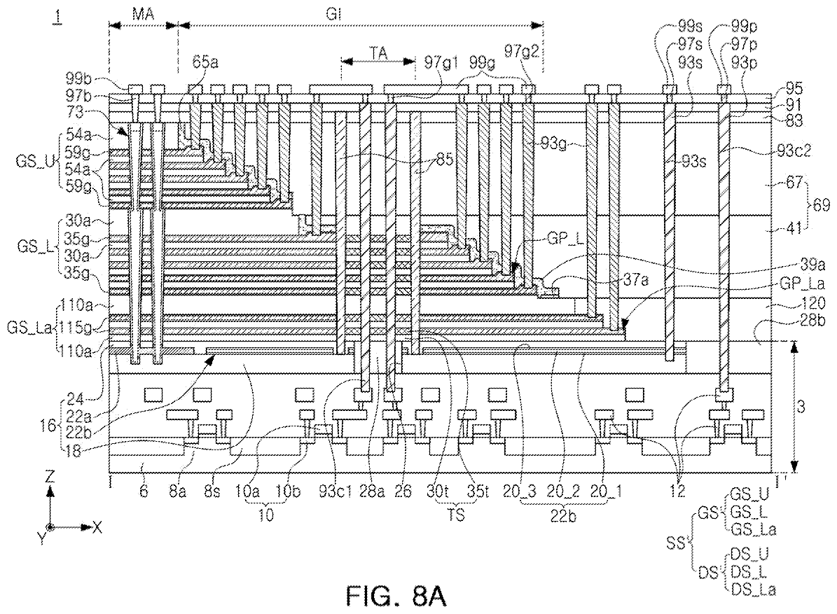

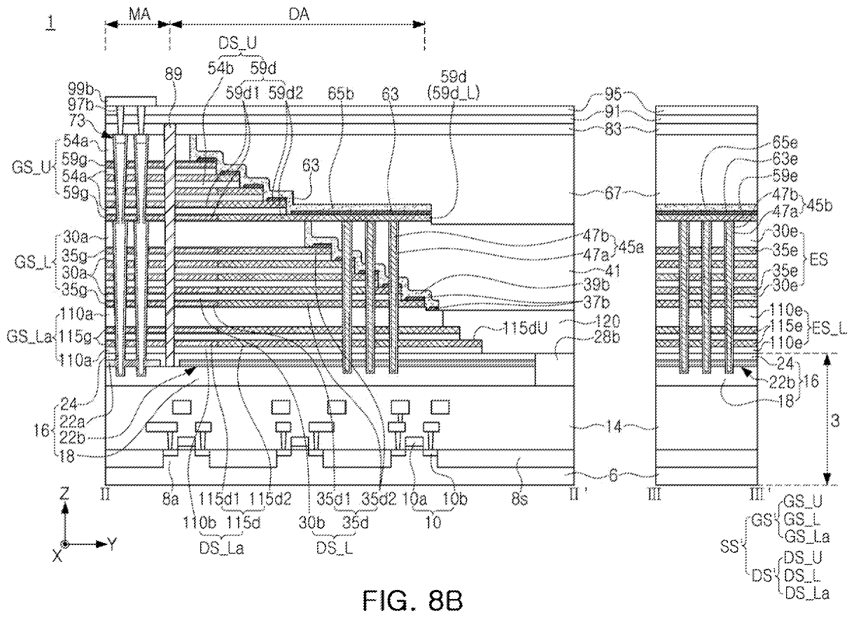

Next, with reference to FIGS. 8A and 8B, the description mainly describes a component modified from that of the semiconductor device 1 according to embodiments. FIGS. 8A and 8B are views respectively schematically illustrating a modified example of the semiconductor device according to embodiments. FIG. 8A is a cross-sectional view illustrating the region taken along line I-I′ in FIG. 1, and FIG. 8B is a cross-sectional view illustrating the regions taken along lines and in FIG. 1.

Referring to FIGS. 8A and 8B, the stack structure SS (in FIGS. 2A to 3B) may be modified into a stack structure SS' further including a lowermost gate stack region GS_La and a lowermost dummy stack region DS_La.

The lowermost layer among the lower interlayer insulating layers 30a and the lower gate layers 35g in the lower gate stack region GS_L may be a lowermost interlayer insulating layer or a lowermost lower gate layer.

A lowermost layer among the dummy lower insulating layers 30b and the dummy lower horizontal layers 35d in the dummy lower stack region DS_L may be a lowermost dummy insulating layer or a lowermost dummy horizontal layer.

The lowermost gate stack region GS_La may be disposed between the lower gate stack region GS_L and the pattern structure 16. The lowermost gate stack region GS_La may include interlayer insulating layers 110a and gate layers 115g stacked alternately on each other. Among the interlayer insulating layers 110a and the gate layers 115g, a lowermost layer may be a lowermost interlayer insulating layer, and an uppermost layer may be an uppermost interlayer insulating layer.

Each of the gate layers 115g may include first and second gate layers respectively corresponding to the first and second gate layers 39g_1 and 39g_2 (in FIG. 3A).

The gate pads GP_La of the gate layers 115g may be arranged in the step shape, and may each have substantially the same thickness as the gate layer 115g. In an implementation, the thickness of each of the gate pads GP_La may be smaller than the thickness of each of the gate pads GP_L and GP_U (in FIG. 3A) described above.

The gate pads GP_La may be referred to as the lower gate pads, and the gate pads GP_L and GP_U in FIG. 3A may be referred to as the upper gate pads. At least one of the lower gate pads GP_La may have a first thickness, and one of the upper gate pads GP_L and GP_U (in FIG. 3A) may have a second thickness greater than the first thickness.

The gate contact plugs 93g may be in contact with and electrically connected to the gate pads GP_L and GP_U (in FIG. 3A), and GP_La. (in FIG. 8A).

The vertical memory structure 73 may penetrate through the stack structure SS' and be in contact with the pattern structure 16.

The lowermost dummy stack region DS_La may be between the dummy lower stack region DS_L and the pattern structure 16. The lowermost dummy stack region DS_La may include dummy lower insulating layers 110b and dummy lower horizontal layers 115d alternately stacked on each other. Among the dummy lower insulating layers 110b and the dummy lower horizontal layers 115d, a lowermost layer may be a lowermost dummy lower insulating layer, and an uppermost layer may be an uppermost dummy lower insulating layer.

In an implementation, each of the dummy lower horizontal layers 115d may include a first horizontal portion 115d1 and a second horizontal portion 115d2. The first horizontal portion 115d1 may be formed of the same material as the first horizontal portion 35d1 illustrated in FIG. 2B, and the second horizontal portion 115d2 may be formed of the same material as the second horizontal portion 35d2 illustrated in FIG. 2B. The dummy lower horizontal layers 115d may include end portions 115dU arranged in the step shape.

The first vertical dummy structure 45a may penetrate through the lowermost dummy stack region DS_La and be in contact with the pattern structure 16.

The semiconductor device 1 may further include a lowermost capping insulating layer 120 covering a portion of the lowermost gate stack region GS_La and a portion of the lowermost dummy stack region DS_La. The lowermost capping insulating layer 120 may be formed of, e.g., silicon oxide.

An upper surface of the lowermost capping insulating layer 120 may be in contact with a lower surface of the lower capping insulating layer 41, The lowermost capping insulating layer 120 may be in contact with the upper and side surfaces of the end portions 115dU of the dummy lower horizontal layers 115d.

The semiconductor device 1 may further include a lowermost edge stack structure ES L between the pattern structure 16 and an edge stack structure ES.

The lowermost edge stack structure ES_L may include edge insulating layers 110e and edge horizontal layers 115e alternately stacked on each other. Among the edge insulating layers 110e and the edge horizontal layers 115e, a lowermost layer may be a lowermost edge insulating layer, and an uppermost layer may be a uppermost edge insulating layer.

The second vertical dummy structure 45b may penetrate through the lowermost edge stack structure ES_L and be in contact with the pattern structure 16.

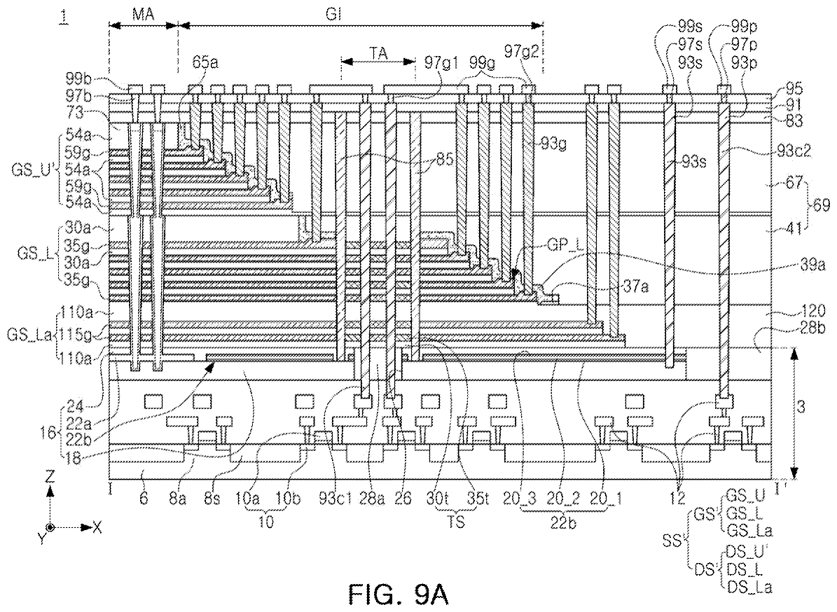

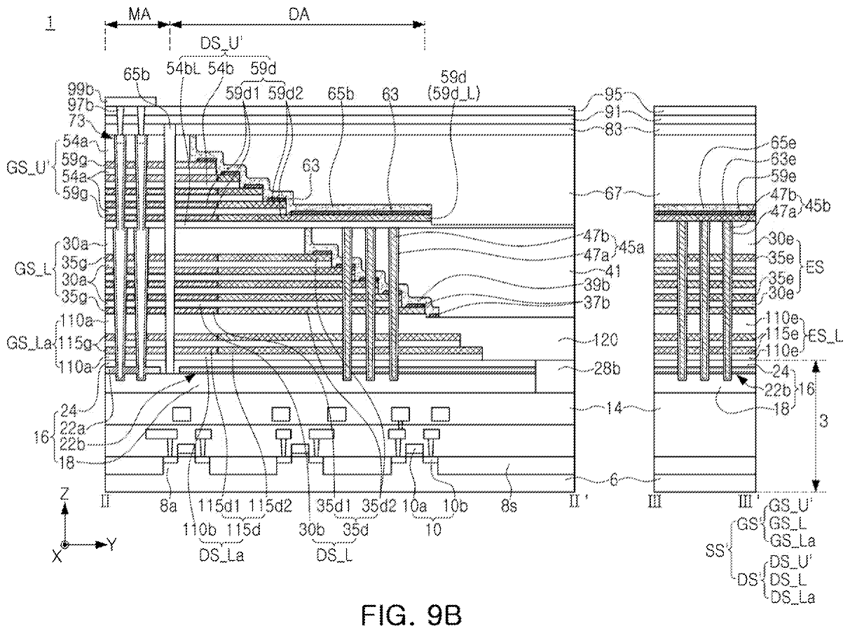

Next, with reference to FIGS. 9A and 9B, the description mainly describes a component modified from that of the semiconductor device 1 according to embodiments. FIGS. 9A and 9B are views respectively schematically illustrating a modified example of the semiconductor device according to embodiments. FIG. 9A is a cross-sectional view illustrating the region taken along line I-I′ in FIG. 1, and FIG. 9B is a cross-sectional view illustrating the regions taken along lines and in FIG. 1.

Referring to FIGS. 9A and 9B, the stack structure SS (in FIGS. 5A and 5B) may be modified into the stack structure SS' further including the lowermost gate stack region GS_La between the lower gate stack region GS_L and the pattern structure 16, and the lowermost dummy stack region DS_La between the dummy lower stack region DS_L and the pattern structure 16, as described with reference to FIGS. 8A and 8B.

The semiconductor device 1 may further include the lowermost edge stack structure ES_L between the pattern structure 16 and the edge stack structure ES, as described with reference to FIG. 8B.

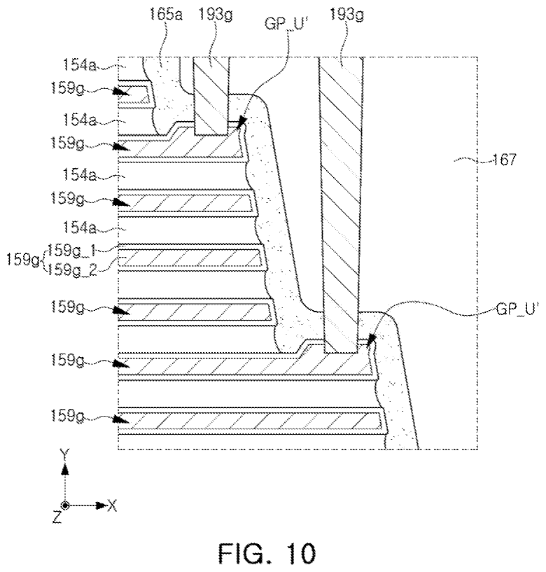

Next, with reference to FIG. 10, the description mainly describes a component modified from that of the semiconductor device 1 according to embodiments. FIG. 10 is a view schematically illustrating a modified example of the semiconductor device according to embodiments. The description describes a modified example of the gate layers 159g including the gate pads GP_U arranged at different height levels and sequentially arranged in the first direction X.

Referring to FIG. 10, interlayer insulating layers 154a and gate layers 159g may be alternately and repeatedly stacked on each other. The gate layers 159g may include gate pads GP_U sequentially arranged in the first direction X and each having an increased thickness.

The plurality of gate layers 159g may each be between a height level of the pair of adjacent gate pads GP_U of the gate pads GP_U sequentially arranged in the first direction X and each having the increased thickness.

Each of the gate layers 159g may include a first gate layer 159g_1 and a second gate layer 159g_2. The first gate layer 159g_1 may cover the upper and lower surfaces of the second gate layer 159g_2, and may partially cover a side surface of the second gate layer 159g_2.

The semiconductor device 1 may further include an insulating liner 165a covering end portions of the gate layers 159g in the first direction X and a capping insulating layer 167 covering the insulating liner 165a. Gate contact plugs 193g may penetrate through the capping insulating layer 167 and the insulating liner 165a and be in contact with the gate pads GP_U.

Some of the interlayer insulating layers 30a and gate layers 35g in the lower gate stack region GS_L may be replaced with the interlayer insulating layers 154a and the gate layers 159g.

Some of the interlayer insulating layers 54a and gate layers 59g in the upper gate stack region GS_U may be replaced with the interlayer insulating layers 154a and the gate layers 159g.

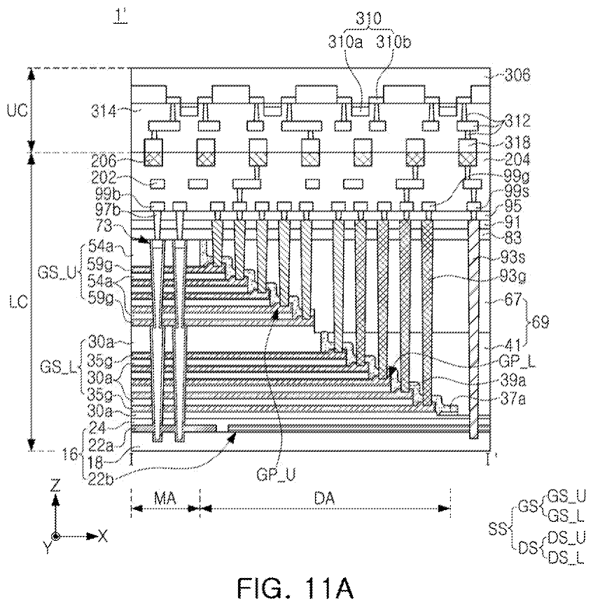

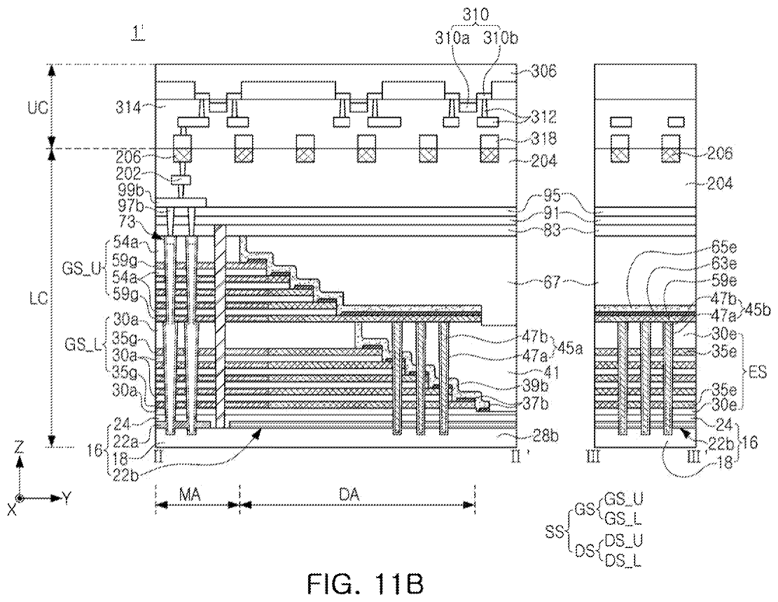

In the semiconductor device 1 according to any one of the embodiments described above with reference to FIGS. 2A to 9B, the peripheral circuit 10 and the peripheral circuit wiring 12 may be under the stack structure SS. The peripheral circuit 10 and the peripheral circuit wiring 12 may be modified to be on the stack structure SS. An exemplary example modified in this manner is described with reference to FIGS. 11A and 11B.

FIGS. 11A and 11B are views respectively schematically illustrating a modified example of a semiconductor device according to embodiments. FIG. 11A is a cross-sectional view illustrating the region taken along line I-I′ in FIG. 1, and FIG. 11B is a cross-sectional view illustrating the regions taken along lines II-II′ and in FIG. 1.

Referring to FIGS. 11 and 11B, a semiconductor device 1′ in the modified example may include a lower chip structure LC and an upper chip structure UC in contact with the lower chip structure LC.

The lower chip structure LC may include the pattern structure 16 to the bit line 99b, the source connection wiring 99s and the gate connection wiring 99g in any one of the embodiments described above with reference to FIGS. 2A to 9B. In an implementation, the lower chip structure LC may include the vertical memory structure 73, the first and second vertical dummy structures 45a and 45b, and the capping structure 69 in any one of the embodiments described above with reference to FIGS. 2A to 9B.

In an implementation, the lower chip structure LC may not include the through region TA or the dam structure 85 described with reference to FIG. 2A.

The lower chip structure LC may further include an insulating structure 204 on the third upper insulating layer 95 in any one of the embodiments described above with reference to FIGS. 2A to 9B, a connection wiring 202 in the insulating structure 204, and lower bonding pads 206 coplanar with an upper surface of the insulating structure 204.

The upper chip structure UC may include a substrate 306, peripheral circuits 310 disposed below the substrate 306, peripheral circuit wiring 312 below the peripheral circuits 310 and electrically connected to the peripheral circuits 310, an insulating structure 314 below the substrate 306 and covering the peripheral circuits 310 and the peripheral circuit wiring 312, and upper bonding pads 318 disposed in the insulating structure 314 and having a lower surface coplanar with a lower surface of the insulating structure 314. The peripheral circuit 310 may include a transistor including a peripheral gate 310a and a peripheral source/drain 310b.

The lower chip structure LC may be bonded to the upper chip structure UC. In an implementation, the insulating structure 204 of the lower chip structure LC and the insulating structure 314 of the upper chip structure UC may be in contact with each other to be bonded to each other, and the lower bonding pads 206 and the upper bonding pads 318 may be in contact with each other to be bonded to each other.

The lower bonding pads 206 and the upper bonding pads 318 may include the same metal material, e.g., copper.

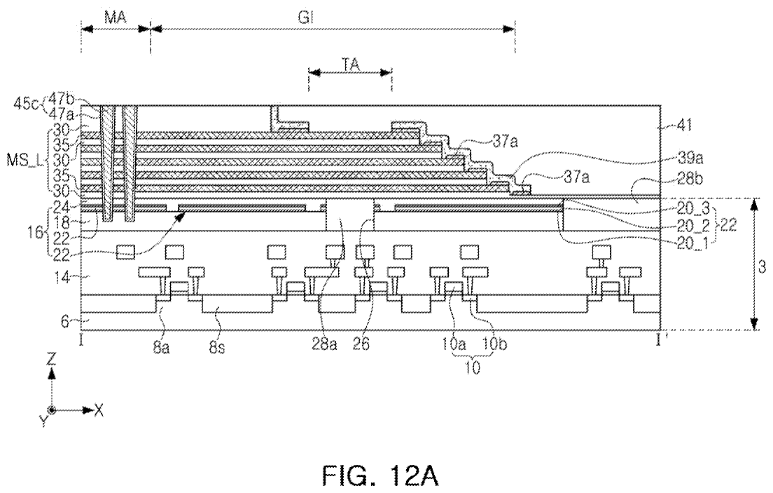

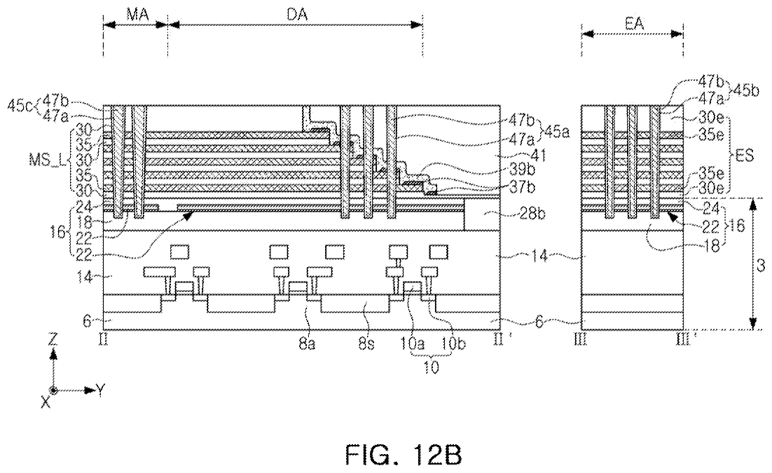

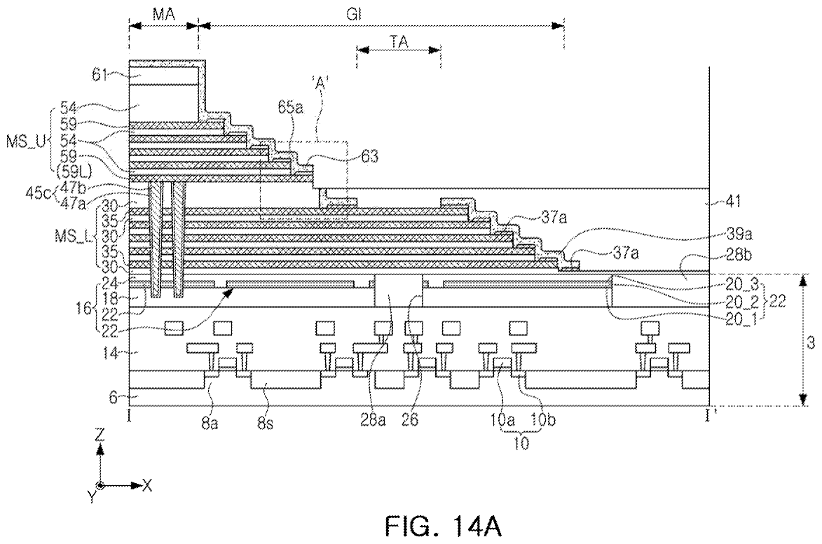

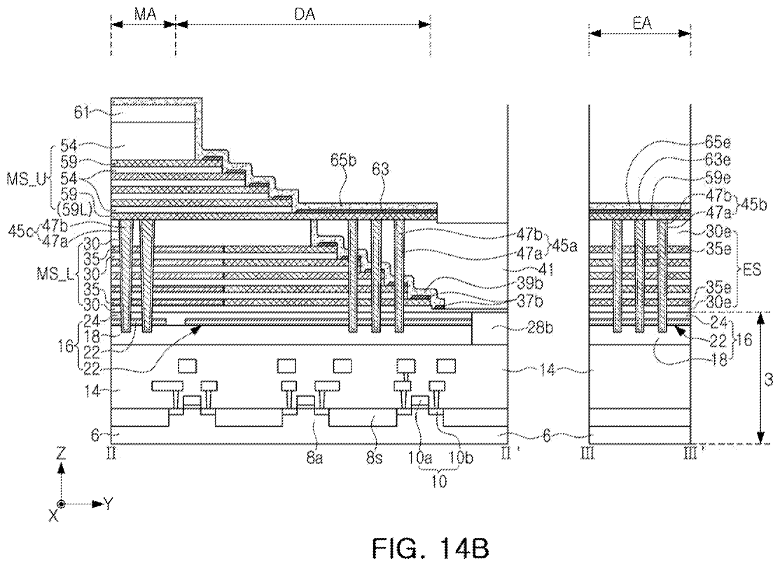

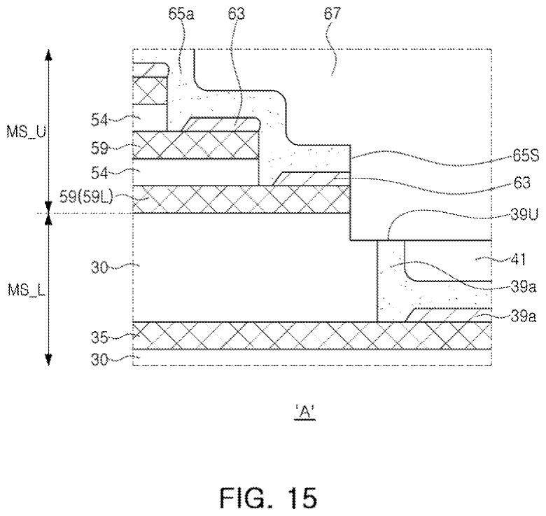

Next, with reference to FIGS. 1 and 12A to 16B, the description describes an exemplary example of a method of manufacturing a semiconductor device according to embodiments. FIGS. 12A to 16B are views respectively schematically illustrating stages in a method of manufacturing a semiconductor device according to embodiments. With respect to FIGS. 12A to 16B, FIGS. 12A, 13A, 14A and 16A are cross-sectional views each illustrating the region taken along line I-I′ in FIG. 1, FIGS. 12B, 13B, 14B and 16B are cross-sectional views each illustrating regions taken along line and in FIG. 1, and FIG. 15 is a partially enlarged view illustrating a region marked with ‘A’ in FIG. 14A.

Referring to FIGS. 1, 12A and 12B, a lower structure 3 may be formed. The lower structure 3 may be formed by forming a device isolation region 8s defining active regions 8a on a substrate 6, forming peripheral circuits 10 on the active regions 8a, and forming a circuit wiring 12 on the peripheral circuits 10 and electrically connected to the peripheral circuits 10, and a lower insulating structure 14 covering the peripheral circuits 10 and the circuit wiring 12. The peripheral circuit 10 may include a transistor including a peripheral gate 10a and a peripheral source/drain 10b.

The substrate 6 may be a semiconductor substrate such as a single crystal silicon substrate.

The lower structure 3 may be formed by forming a pattern structure 16, having an opening 26, on the lower insulating structure 14, and further forming a gap fill insulating layer 28a filling the opening 26 and an intermediate insulating layer 28b covering a side surface of the pattern structure 16.

The gap fill insulating layer 28a and the intermediate insulating layer 28b may be formed of the same material as each other, e.g., silicon oxide.

The pattern structure 16 may be formed by forming a lower layer 18, by forming a patterned intermediate layer 22 on the lower layer 18, and forming an upper layer 24 above the lower layer 18 and covering the intermediate layer 22. A portion of the upper layer 24 may penetrate through the intermediate layer 22 and be in contact with the lower layer 18.

The lower layer 18 may include a silicon layer, e.g., a polysilicon layer of an N-type conductivity.

The intermediate layer 22 may include a first layer 20_1, a second layer 20b_2, and a third layer 20b_3, which are sequentially stacked.

The upper layer 24 may include the silicon layer, e.g., the polysilicon layer of an N-type conductivity.

A lower mold structure MS_L and an edge stack structure ES may be formed on the lower structure 3.

At least one side of the lower mold structure MS_L may have a step shape. In an implementation, a first side of the lower mold structure MS_L in the first direction X may have a first lower step shape and a second side of the lower mold structure MS_L in the second direction Y may have a second lower step shape.

The lower mold structure MS_L may include lower insulating layers 30 and lower mold layers 35 alternately and repeatedly stacked on each other.

Among the lower insulating layers 30 and the lower mold layers 35 of the lower mold structure MS_L, a lowermost layer may be a lowermost lower insulating layer, and an uppermost layer may be an uppermost lower insulating layer.

In an implementation, the lower insulating layer 30 may be formed of a first insulating material such as silicon oxide, and the lower mold layer 35 may be formed of a second insulating material such as silicon nitride having etch selectivity for the first insulating material.

In an implementation, the lower insulating layer 30 may be formed of an insulating material such as silicon oxide, and the lower mold layer 35 may be formed of a conductive material.

A lowermost edge stack structure ES_L may include edge insulating layers 30e and edge dummy horizontal layers 35e alternately stacked on each other. The edge dummy horizontal layers 35e may be at substantially the same height level as the lower mold layer 35, and may be formed of the same material as the lower mold layer 35.

First lower additional insulating layers 37a may cover respective end portions of the lower mold layers 35 arranged in the first lower step shape in the first side of the lower mold structure MS_L in the first direction X, and second lower additional insulating layers 37b may cover respective end portions of the lower mold layers 35 arranged in the second lower step shape in the second side of the lower mold structure MS_L in the second direction Y.

A first lower insulating liner 39a may cover the respective end portions of the lower mold layers 35 arranged in the first lower step shape in the first side of the lower mold structure MS_L in the first direction X and the first lower additional insulating layers 37a, and a second lower insulating liner 39b may cover respective end portions of the lower mold layers 35 arranged in the second lower step shape in the second side of the lower mold structure MS_L in the second direction Y and the second lower additional insulating layers 37b.

A patterning process may be performed to pattern the second lower additional insulating layers 37b and the second lower insulating liner 39b in addition to patterning the first lower additional insulating layers 37a and the first lower insulating liner 39a.

A lower capping insulating layer 41 may be formed, and then a flattening process may be performed until an upper surface of the lower mold structure MS_L is exposed.

A sacrificial vertical structure 45c, penetrating through the lower mold structure MS_L on a memory cell region MA and in contact with the lower layer 18 of the pattern structure 16 may be simultaneously formed with a first vertical dummy structure 45a penetrating through the lower mold structure MS_L in a dummy region DA and in contact with the lower layer 18 of the pattern structure 16, and a second vertical dummy structure 45b penetrating through the edge stack structure ES of an edge region EA and in contact with the lower layer 18 of the pattern structure 16.

Each of the sacrificial vertical structure 45c and first and second vertical dummy structures 45a and 45b may include a dummy pattern 47b and a dummy liner 47a covering the side and bottom surfaces of the dummy pattern 47b.

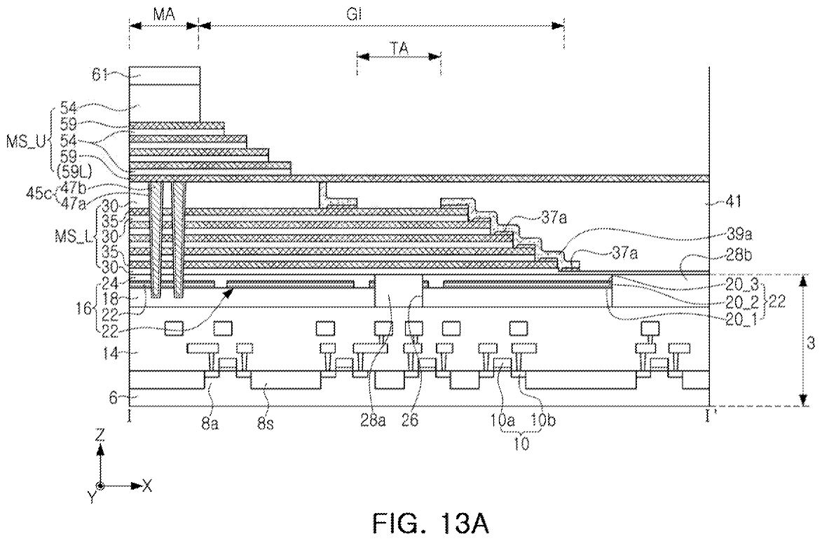

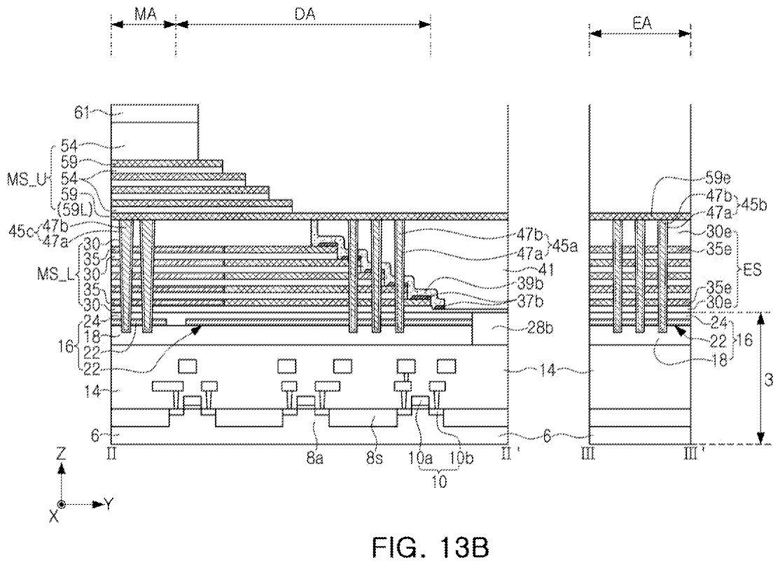

Referring to FIGS. 1, 13A and 13B, an upper mold structure MS U may be formed on the lower capping insulating layer 41 and the lower mold structure MS_L. A mask pattern 61 may be formed on the upper mold structure MS U.

The upper mold structure MS U may include upper insulating layers 54 and upper mold layers 59 alternately and repeatedly stacked on each other.

In an implementation, among the upper insulating layers 54 and the upper mold layers 59 of the upper mold structure MS U, a lowermost layer may be a lowermost upper mold layer 59L, and an uppermost layer may be an uppermost upper insulating layer.

In an implementation, among the upper insulating layers 54 and the upper mold layers 59 of the upper mold structure MS U, a lowermost layer may be a lowermost upper insulating layer, and an uppermost layer may be an uppermost upper insulating layer.

The upper insulating layer 54 and the upper mold layer 59, at a level higher than the lowermost upper mold layer 59L, among the upper insulating layers 54 and the upper mold layers 59 of the upper mold structure MS_U may be patterned to obtain the step shape. In an implementation, the lowermost upper mold layer 59L may cover the lower capping insulating layer 41, the lower mold structure MS_L and the edge stack structure ES.

A portion of the lowermost upper mold layer 59L, covering the edge stack structure ES, may be referred to as an edge horizontal layer 59e as illustrated in FIG. 2B.

Referring to FIGS. 1, 14A, 14B and 15, additional insulating layers 63 may be formed covering an exposed upper surface of the lowermost upper mold layer 59L, and covering the upper surfaces of the step-shaped ends of the upper insulating layers 54 each at a level higher than the lowermost upper mold layer 59L.

An additional insulating layer covering the upper surface of the edge horizontal layer 59e may be referred to as an edge additional insulating layer 63e.

Upper insulating liners 65a and 65b may be formed covering the upper mold structure MS U while covering the additional insulating layers 63 and the edge additional insulating layer 63e.

The patterning process may be performed to pattern the upper insulating liners 65a and 65b and the additional insulating layers 63. In an implementation, the upper insulating liners 65a and 65b may respectively be formed of the first upper insulating liner 65a as illustrated in FIG. 2A and the second upper insulating liner 65b as illustrated in FIG. 2B. In an implementation, the lowermost upper mold layer 59L may be patterned while patterning the upper insulating liner 65a and 65b and the additional insulating layers 63.

A side surface 65S of the first upper insulating liner 65a may be vertically aligned with a side surface of the lowermost upper mold layer 59L.

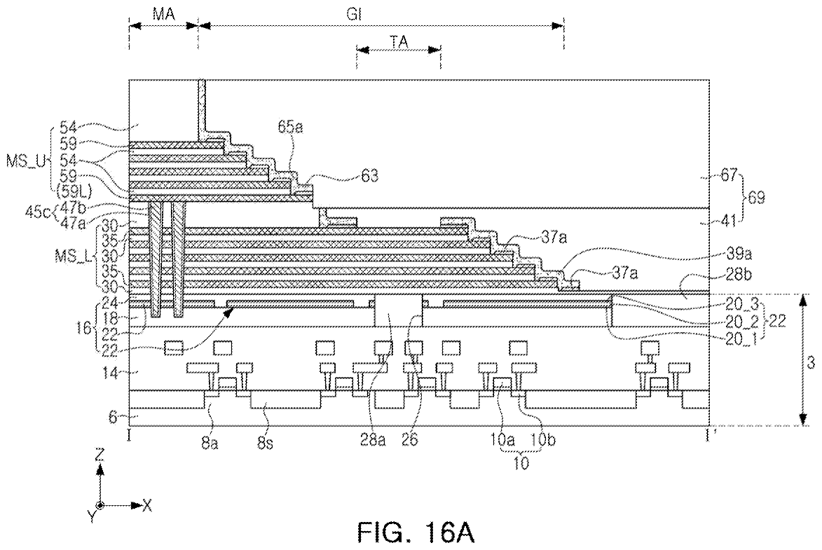

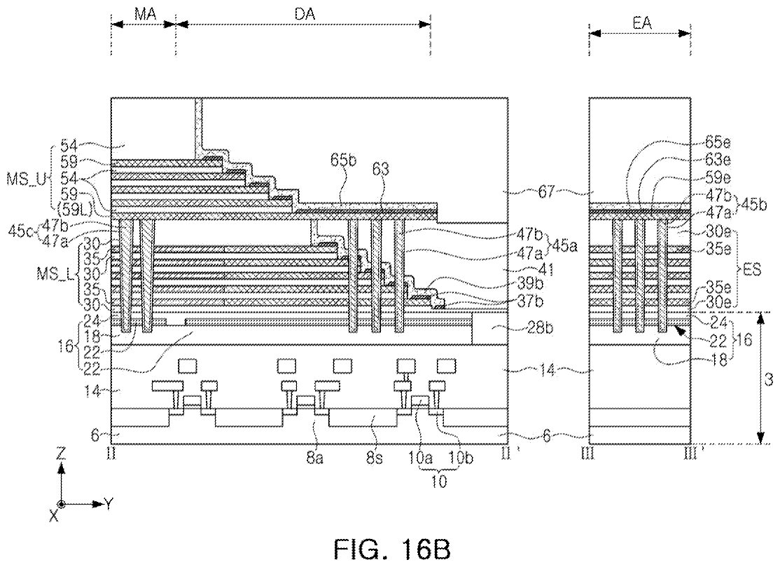

Referring to FIGS. 1, 16A and 16B, an upper capping insulating layer 67 may be formed, and the flattening process may be performed until an upper surface of the upper mold structure MS U is exposed. Here, the mask pattern 61 (in FIGS. 14A and 14B) may be removed. A capping structure 69 may include the upper capping insulating layer 67 and the lower capping insulating layer 41.

Referring to FIGS. 1, 2A, 2B, 3A and 3B again, on the memory cell region MA, an upper hole may be formed penetrating through the upper mold structure MS U (in FIG. 16A) and exposing the sacrificial vertical structure 45c, a lower hole may be formed by removing the sacrificial vertical structure 45c exposed by the upper hole, and a vertical memory structure 73 may be formed filling the lower and upper holes.

A first upper insulating layer 83 may be subsequently formed. A dam structure 68 may be formed penetrating through the first upper insulating layer 83, the capping structure 69, and the lower mold structure MS_L (in FIG. 16A). A region of the lower mold structure MS_L (in FIG. 16A) surrounded by the dam structure 68 may be defined as a through-insulating structure TS.

Separation trenches may be formed, each penetrating through the first upper insulating layer 83 and extending downwardly to penetrate through the upper and lower mold structures MS U and MS_L (in FIG. 16A), an opening passing through a data storage structure 75 (in FIG. 3B) of the vertical memory structure 73 and exposing the channel layer 77 may be formed in addition to removing a portion of the intermediate layer 22, exposed by the separation trench, and a first intermediate layer 22a may be formed filling the opening. A remaining portion of the intermediate layer 22 may be defined as a second intermediate layer 22b.

Portions of the upper and lower mold layers 35 and 59 of the upper and lower mold structures MS U and MS_L (in FIG. 16A) exposed by the separation trenches may respectively be replaced with upper and lower gate layers 59g and 35g as illustrated in FIGS. 2A to 3B and first horizontal portions 35d1 and 59d1 as illustrated in FIG. 2B. Rest portions of the upper and lower mold layers 35 and 59 of the upper and lower mold structures MS U and MS_L (in FIG. 16A) may respectively be defined as second horizontal portions 35d2 and 59d2 in FIGS. 2A and 2B. Separation structures 89 filling the separation trenches may be formed.

Accordingly, the upper and lower mold structures MS U and MS_L (in FIG. 16A) may be formed of a stack structure SS as in FIGS. 2A and 2B.

Then, plug and wiring processes may be performed to form gate contact plugs 93g, a source contact plug 93s, a first through-contact plug 93c1, a second through-contact plug 93c2, a bit line contact plug 97b, a first gate connection plug 97g1, a second gate connection plugs 97g2, a source connection plug 97s, a peripheral connection plug 9′7p, a bit line 99b, a gate connection wiring 99g, a source connection wiring 99s and a peripheral connection wiring 99p, as illustrated in FIGS. 2A and 2B.

According to the above-described embodiments, the first vertical dummy structure 45a may be used as a monitoring pattern of a semiconductor process to stably form the vertical memory structure 73. In an implementation, the first vertical dummy structure 45a may be used as a monitoring pattern for a photo process and an etching process to stably form the sacrificial vertical structure 45c (in FIGS. 12A and 12B) for forming the vertical memory structure 73. Therefore, the vertical memory structure 73 may be formed without defects, thereby improving productivity of the semiconductor device 1, and the vertical memory structure 73 may be reliably formed without deformation, thereby improving reliability of semiconductor device 1.

The first vertical dummy structure 45a may help prevent the deformation, e.g., bending of the semiconductor device 1. Therefore, the semiconductor device 1 may be manufactured stably and reliably while increasing the number of the gate layers 35g and 59g, which are vertically stacked, by including the first vertical dummy structure 45a. Therefore, it is possible to improve an integration degree of the semiconductor device 1.

According to the embodiments, the second vertical dummy structure 45b penetrating through the edge stack structure ES on the edge region EA may be used as an align key in the semiconductor process.

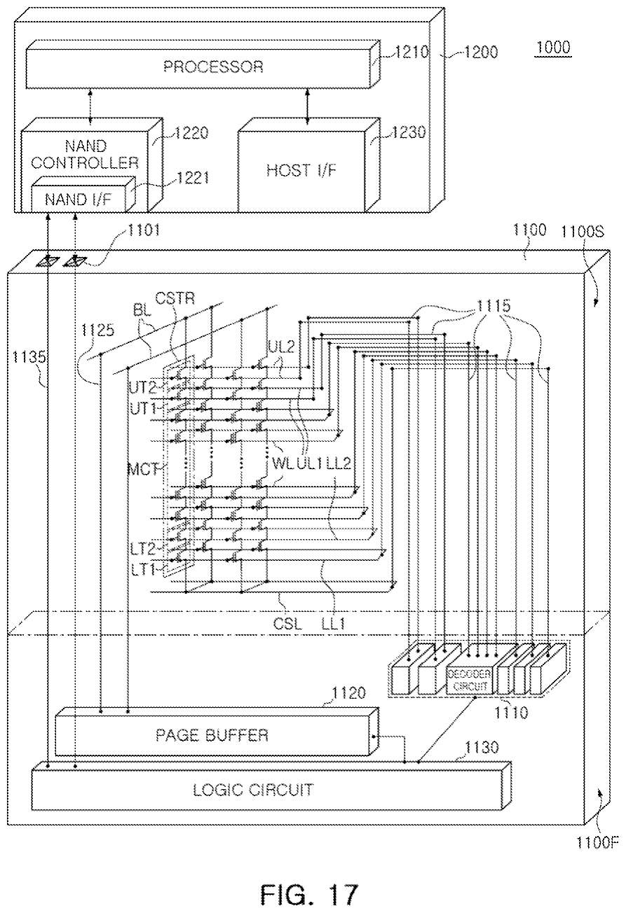

Next, with reference to each of FIGS. 17, 18 and 19, the description describes a data storage system including a semiconductor device according to embodiments.

FIG. 17 is a view schematically illustrating the data storage system including a semiconductor device according to embodiments.

Referring to FIG. 17, a data storage system 1000 according to embodiments may include a semiconductor device 1100 and a controller 1200 electrically connected with the semiconductor device 1100 to control the semiconductor device 1100. The data storage system 1000 may be a storage device including the semiconductor device 1100 or an electronic device including the storage device. In an implementation, the data storage system 1000 may be a solid state drive (SSD) device, a universal serial bus (USB), a computing system, a medical device or a communications device, which includes the semiconductor device 1100.

In an implementation, the data storage system 1000 may be an electronic system for storing data.

The semiconductor device 1100 may be the semiconductor device according to any one of the embodiments described above with reference to FIGS. 1 to 11B. The semiconductor device 1100 may include a first structure 1100F and a second structure 1100S on the first structure 1100F.

The first structure 1100F may be a peripheral circuit structure including a decoder circuit 1110, a page buffer 1120 and a logic circuit 1130. In an implementation, the first structure 1100F may include the peripheral circuit structure PS including the peripheral circuit described above. The peripheral circuit may be a transistor having a peripheral circuit structure including the decoder circuit 1110, the page buffer 1120 and the logic circuit 1130.

The peripheral circuit 10 (in FIGS. 2A and 2B) described above may include the decoder circuit 110 and the page buffer 1120.

The second structure 1100S may be a memory structure including a bit line BL, a common source line CSL, word lines WL, first and second gate upper lines UL1 and UL2, first and second gate lower lines LL1 and LL2, and a memory cell string CSTR disposed between the bit line BL and the common source line CSL.

The bit line BL may be the above-described bit line 99b (in FIGS. 2A and 2B). The above-described pattern structure 16 may include the common source line CSL. The first and second gate lower lines LL1 and LL2 may be formed of some of the lower gate layers 35g (in FIGS. 2A to 7B and 11A) or may be the above-described lowermost gate layers 115g (in FIGS. 8A to 9B).

Among the lower and upper gate layers 35g and 59g (in FIGS. 2A to 11B) described above, the gate layers therebetween may be the word lines WL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT between lower transistors LT1 and LT2 and the upper transistors UT1 and UT2. The number of the lower transistors LT1 and LT2 and the number of the upper transistors UT1 and UT2 may be variously changed based on the embodiments.

In the embodiments, the upper transistor UT1 or UT2 may be a string select transistor, and the lower transistor LT1 or LT2 may be a ground select transistor. The gate lower lines LL1 and LL2 may respectively be gate electrodes of the lower transistors LT1 and LT2. The word lines WL may be gate electrodes of the memory cell transistors MCT, and the gate upper lines UL1 and UL2 may respectively be gate electrodes of the upper transistors UT1 and UT2.

The gate layers 35g and 59g described above may include the gate lower lines LL1 and LL2, the word lines WL and the gate upper lines UL1 and UL2.

In an implementation, the lower transistor LT1 or LT2 may be a lower erase control transistor LT1 or a ground select transistor LT2, which are connected in series with each other. The upper transistor UT1 or UT2 may be the string select transistor UT1 or the upper erase control transistor UT2, which are connected in series with each other. At least one of the lower erase control transistor LT1 and the upper erase control transistor UT1 may be used for an erase operation to delete data stored in the memory cell transistors MCT by using a gate induce drain leakage (GIDL) phenomenon.

The common source line CSL, the first and second gate lower lines LL1 and LL2, the word lines WL and the first and second gate upper lines UL1 and UL2 may be electrically connected to the decoder circuit 1110 through first connecting wirings 1115 extended from the first structure 1100F to the second structure 1100S. The gate connection wirings 99g (in FIG. 2A) and the first through-contact plugs 93c1 (in FIG. 2A), which are described above, may be the first connection wirings 1115.

The bit lines BL may be electrically connected to the page buffer 1120 through second connection wirings 1125 extended from the first structure 1100F to the second structure 1100S.

In the first structure 1100F, the decoder circuit 1110 and the page buffer 1120 may perform a control operation on at least one selected memory cell transistor of the plurality of memory cell transistors MCT. The decoder circuit 1110 and the page buffer 1120 may be controlled by the logic circuit 1130.

The semiconductor device 1100 may further include an input/output pad 1101.

The semiconductor device 1100 may communicate with the controller 1200 through the input/output pad 1101 electrically connected to the logic circuit 1130. The input/output pad 1101 may be electrically connected to the logic circuit 1130 through an input/output connection wiring 1135 extended from the first structure 1100F to the second structure 1100S. Accordingly, the controller 1200 may be electrically connected to the semiconductor device 1100 through the input/output pad 1101 and may control the semiconductor device 1100.

The controller 1200 may include a processor 1210, a NAND controller 1220 and a host interface 1230. In an implementation, the data storage system 1000 may include the plurality of semiconductor devices 1100. In this case, the controller 1200 may control the plurality of semiconductor devices 1100.

The processor 1210 may control an overall operation of the data storage system 1000 including the controller 1200. The processor 1210 may be operated based on a predetermined firmware, and may control the NAND controller 1220 to access the semiconductor device 1100. The NAND controller 1220 may include a NAND interface 1221 handling communications with the semiconductor device 1100. The NAND interface 1221 may be used for transmitting a control command for controlling the semiconductor device 1100, data to be recorded in the memory cell transistors MCT of the semiconductor device 1100, data to be read from the memory cell transistors MCT of the semiconductor device 1100, or the like. The host interface 1230 may provide a communications function between the data storage system 1000 and an external host. When receiving a control command from then external host through the host interface 1230, the processor 1210 may control the semiconductor device 1100 in response to the control command.

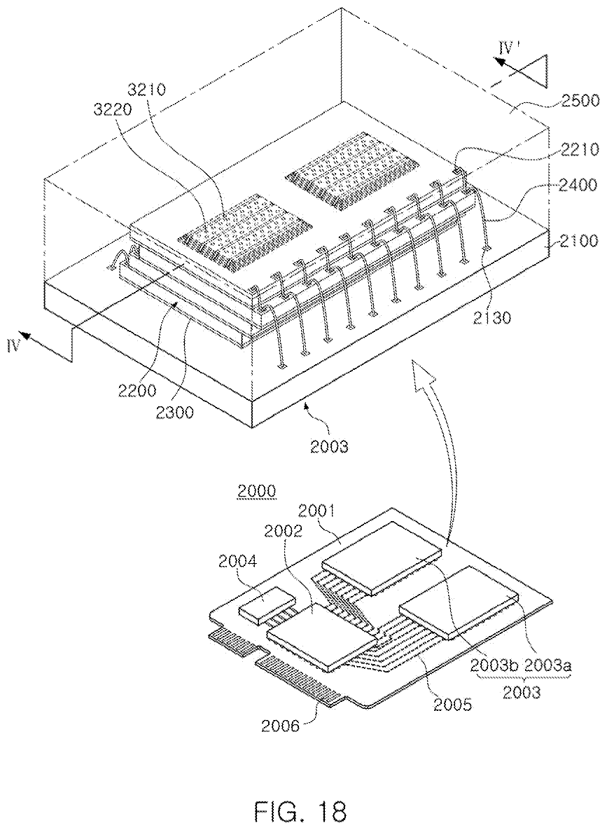

FIG. 18 is a view schematically illustrating the data storage system including a semiconductor device according to embodiments.

Referring to FIG. 18, a data storage system 2000 according to embodiments may include a main substrate 2001, a controller 2002 mounted on the main substrate 2001, at least one semiconductor packages 2003 and a dynamic random access memory (DRAM) 2004. The semiconductor package 2003 and the DRAM 2004 may be connected to the controller 2002 by wiring patterns 2005 formed on the main substrate 2001.

The main substrate 2001 may include a connector 2006 including a plurality of pins coupled to the external host. The number and position of the plurality of pins in the connector 2006 may be changed based on a communications interface between the data storage system 2000 and the external host. In an implementation, the data storage system 2000 may communicate with the external host by using one of the interfaces such as a universal serial bus (USB), a peripheral component interconnect express (PCI-Express), a serial advanced technology attachment (SATA) and M-Phy for universal flash storage (UFS). In an implementation, the data storage system 2000 may be operated by power supplied from the external host through the connector 2006. The data storage system 2000 may further include a power management integrated circuit (PMIC) for distributing power supplied from the external host to the controller 2002 and the semiconductor package 2003.

The controller 2002 may record data in the semiconductor package 2003 or read data from the semiconductor package 2003, and may help improve an operation speed of the data storage system 2000.

The DRAM 2004 may be a buffer memory for mitigating a speed difference between the semiconductor package 2003, which is a data storage space, and the external host. The DRAM 2004 included in the data storage system 2000 may also be operated as a kind of cache memory, and may also provide a space for temporarily storing data in an operation of controlling the semiconductor package 2003. When the DRAM 2004 is included in the data storage system 2000, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the semiconductor chips 2200 may include a semiconductor device according to any one of the embodiments described above with reference to FIGS. 1 to 11B.

Each of the first and second semiconductor packages 2003a and 2003b may include a package substrate 2100, the semiconductor chips 2200 on a package substrate 2100, adhesive layers 2300 respectively on lower surfaces of the semiconductor chips 2200, a connection structure 2400 electrically connecting the semiconductor chips 2200 and the package substrate 2100 to each other, and a molding layer 2500 above the package substrate 2100 and covering the semiconductor chips 2200 and the connection structure 2400.

The package substrate 2100 may be a printed circuit board including package top pads 2130. Each of the semiconductor chips 2200 may include an input/output pad 2210.

In an implementation, the connection structure 2400 may be a bonding wire electrically connecting the input/output pad 2210 and the package top pads 2130 to each other. In an implementation, in each of the first and second semiconductor packages 2003a and 2003b, the semiconductor chips 2200 may be electrically connected to each other by using a bonding wire method, and may be electrically connected to the package top pads 2130 of the package substrate 2100. In an implementation, in each of the first and second semiconductor packages 2003a and 2003b, the semiconductor chips 2200 may be electrically connected to each other by a connection structure including a through electrode (e.g., through silicon via (TSV)) instead of the connection structure 2400 using the bonding wire method.

In an implementation, the controller 2002 and the semiconductor chips 2200 may be included in one package. In an implementation, the controller 2002 and the semiconductor chips 2200 may be mounted on a separate interposer substrate different from the main substrate 2001, and the controller 2002 and the semiconductor chips 2200 may then be connected to each other by wiring formed on the interposer substrate.

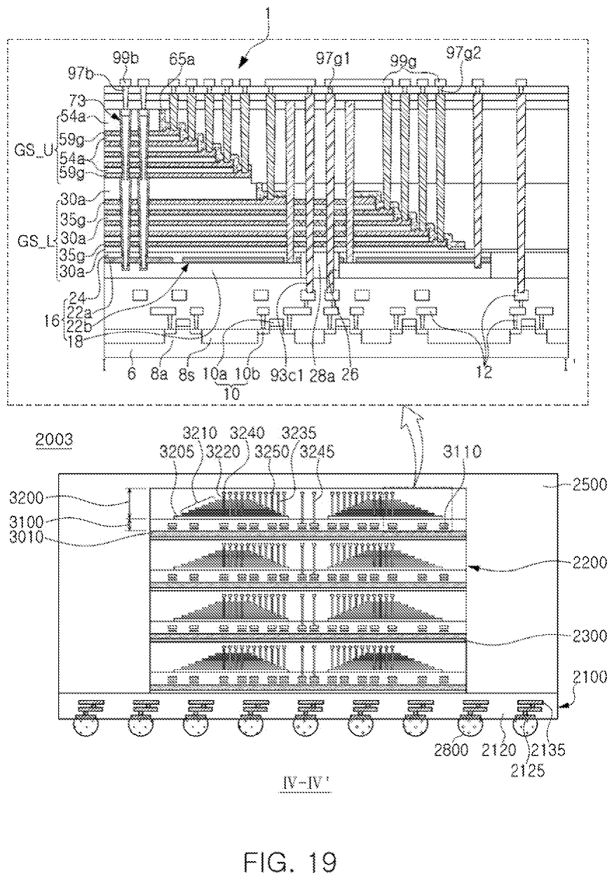

FIG. 19 is a cross-sectional view schematically illustrating a semiconductor package according to embodiments. FIG. 19 illustrates embodiments of the semiconductor package 2003 illustrated in FIG. 18, and conceptually represents a region cut along a cutting line IV-IV′ of the semiconductor package 2003 in FIG. 18.

Referring to FIG. 19, in the semiconductor package 2003, the package substrate 2100 may be a printed circuit board. The package substrate 2100 may include a package substrate body portion 2120, the package top pads 2130 on an upper surface of the package substrate body portion 2120, lower pads 2125 on a lower surface of the package substrate body portion 2120 or exposed through the lower surface thereof, and internal wirings 2135 in the package substrate body portion 2120 and electrically connecting the top pads 2130 and the lower pads 2125 to each other. The top pads 2130 may be electrically connected to connection structures 2400. The lower pads 2125 may be connected to the wiring patterns 2005 of a main substrate 2001 of the data storage system 2000 as illustrated in FIG. 18 through conductive connection portions 2800.

Each of the semiconductor chips 2200 may include a semiconductor substrate 3010 and a first structure 3100 and a second structure 3200, which are sequentially stacked on each other, on the semiconductor substrate 3010. The first structure 3100 may include a peripheral circuit region including peripheral wirings 3110. A second structure 3200 may include a common source line, a stack structure ST on the common source line, vertical memory structures 3220 and separation structures BSS that penetrate through the stack structure ST, bit lines 3240 electrically connected to the vertical memory structures 3220, and gate connection wirings electrically connected to the word lines WL of the stack structure ST. In an implementation, the vertical memory structures 3220 may be the above-described vertical memory structures 73 (in FIGS. 2A and 3B). The pattern structure 16 (in FIG. 2A) described above may include the common source line.

In each of the semiconductor chips 2200, side surfaces of the stack structure ST may be in contact with the molding layer 2500.

The first structure 3100 may include the first structure 1100F illustrated in FIG. 17, and the second structure 3200 may include the second structure 1100S illustrated in FIG. 17. For example, a partially enlarged region in FIG. 19, indicated by reference numeral 1, may be the cross-sectional structure illustrated in FIG. 2A. Accordingly, each of the semiconductor chips 2200 may include the semiconductor device 1 or 1′ according to any one of the embodiments described above with reference to FIGS. 1 to 11B.

Each of the semiconductor chips 2200 may include through wirings 3245 electrically connected to the peripheral wirings 3110 of the first structure 3100 and extended into the second structure 3200. The through wiring 3245 may penetrate through the stack structure ST.

Each of the semiconductor chips 2200 may further include an input/output connection wiring 3265 electrically connected to the peripheral wirings 3110 of the first structure 3100 and extended into the second structure 3200, and the input/output pad 2210 electrically connected to the input/output connection wiring 3265.

Each of the semiconductor chips 2200 may include the semiconductor device 1 or 1′ according to any one of the embodiments described above with reference to FIGS. 1 to 11B, and the semiconductor device 1 or 1′ may include the input/output pad 2210. The input/output pad 2210 may be referred to as an input/output pattern. The above-described controller 1200 may be electrically connected to the semiconductor device 1 or 1′ through the input/output pad 2210, and may control the semiconductor device 1 or 1′.

By way of summation and review, as a method for increasing the data storage capacity of a semiconductor device, a semiconductor device may include memory cells arranged in three dimensions instead of memory cells arranged in two dimensions.

As set forth above, according to the embodiments, it is possible to provide the semiconductor device including the vertical memory structure penetrating through the stack structure in the memory cell region and the first vertical dummy structure penetrating through the dummy lower stack region of the stack structure in the dummy region. The first vertical dummy structure may be used as the monitoring pattern of the semiconductor process to stably form the vertical memory structure. The first vertical dummy structure may help prevent deformation, e.g., bending, of a semiconductor device. Therefore, the semiconductor device may be manufactured stably and reliably while increasing the number of the gate layers which are vertically stacked by including the first vertical dummy structure. Therefore, it is possible to improve the integration degree of the semiconductor device.

According to the embodiments, it is possible to provide the semiconductor device including the edge stack structure in the edge region and the second vertical dummy structure penetrating through the edge stack structure. The second vertical dummy structure may be used as the alignment key in the semiconductor process.

One or more embodiments may provide a semiconductor device having improved integration.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a stack structure including a gate stack region and a dummy stack region;
a vertical memory structure penetrating through the gate stack region in a vertical direction; and
a first vertical dummy structure penetrating through at least a portion of the dummy stack region in the vertical direction,
wherein:
the gate stack region includes interlayer insulating layers and gate layers alternately and repeatedly stacked on each other in the vertical direction,
the dummy stack region includes dummy insulating layers and dummy horizontal layers alternately and repeatedly stacked on each other in the vertical direction,
at least one of the dummy horizontal layers and at least one of the gate layers include materials different from each other,
an upper surface of the vertical memory structure is at a higher level than an upper surface of the first vertical dummy structure, and
a lowermost dummy upper horizontal layer of the dummy horizontal layers at a higher level than the first vertical dummy structure overlaps the first vertical dummy structure.

2. The semiconductor device as claimed in claim 1, wherein:
a portion of the dummy stack region has a step shape,
the first vertical dummy structure penetrates through the portion of the dummy stack region, having the step shape, and
at least two dummy horizontal layers at a higher level than the lowermost dummy upper horizontal layer among the dummy horizontal layers do not overlap the first vertical dummy structure.

3. The semiconductor device as claimed in claim 1, further comprising:
an edge stack structure spaced apart from the stack structure;
a second vertical dummy structure penetrating through the edge stack structure; and
an edge horizontal layer overlapping the second vertical dummy structure,
wherein:
the edge stack structure includes edge insulating layers and edge horizontal layers alternately and repeatedly stacked on each other,
the second vertical dummy structure has a same cross-sectional structure as a cross-sectional structure of the first vertical dummy structure,
the edge horizontal layer is at the same level as the lowermost dummy upper horizontal layer, and
the edge horizontal layer includes the same material as at least a portion of the lowermost dummy upper horizontal layer.

4. The semiconductor device as claimed in claim 1, wherein:
the vertical memory structure includes an insulating core region in a channel hole penetrating through the gate stack region; a channel layer covering at least a side surface of the insulating core region; a data storage structure covering at least an outer side surface of the channel layer; and a pad pattern on the insulating core region and in contact with the channel layer, and
the first vertical dummy structure includes a dummy pattern in a dummy hole penetrating through a portion of the dummy stack region; and a dummy liner covering at least a side surface of the dummy pattern,
the dummy pattern includes a material different from a material of the insulating core region, and
the dummy liner includes a material different from a material of the channel layer.

5. The semiconductor device as claimed in claim 1, wherein:
the stack structure includes:
a lower stack structure including a lower gate stack region and a dummy lower stack region; and
an upper stack structure including an upper gate stack region on the lower gate stack region and a dummy upper stack region on the dummy lower stack region,
the lower gate stack region includes lower interlayer insulating layers and lower gate layers alternately and repeatedly stacked on each other,
the dummy lower stack region includes dummy lower insulating layers and dummy lower horizontal layers alternately and repeatedly stacked on each other,
the upper gate stack region includes upper interlayer insulating layers and upper gate layers alternately and repeatedly stacked on each other,
the dummy upper stack region includes dummy upper insulating layers and dummy upper horizontal layers alternately and repeatedly stacked on each other,
the interlayer insulating layers include the lower interlayer insulating layers and the upper interlayer insulating layers,
the gate layers include the lower gate layers and the upper gate layers,
the dummy insulating layers include the dummy lower insulating layers and the dummy upper insulating layers,
the dummy horizontal layers include the dummy lower horizontal layers and the dummy upper horizontal layers, and
the lowermost dummy upper horizontal layer is the lowermost layer among the dummy upper horizontal layer.

6. The semiconductor device as claimed in claim 5, wherein:
end portions of the dummy lower horizontal layers are arranged in a step shape,
end portions of the dummy upper horizontal layers are arranged in a step shape,
the gate layers include a first conductive material,
at least one of the dummy lower horizontal layers includes a first insulating material different from the first conductive material, and
a side surface of the first vertical dummy structure is in contact with the first insulating material of the dummy lower horizontal layer.

7. The semiconductor device as claimed in claim 6, wherein:
at least one of the dummy upper horizontal layers includes the first insulating material, and
the lowermost dummy upper horizontal layer is in contact with the upper surface of the first vertical dummy structure.

8. The semiconductor device as claimed in claim 5, further comprising an additional insulating layer on a portion of the lowermost dummy upper horizontal layer, wherein:
the lowermost dummy upper horizontal layer includes a first region in which the lowermost dummy upper horizontal layer overlaps the dummy upper horizontal layers at a higher level than the lowermost dummy upper horizontal layer of the dummy upper horizontal layers and a second region in which the lowermost dummy upper horizontal layer does not overlap the dummy upper horizontal layers disposed at a higher level than the lowermost dummy upper horizontal layer of the dummy upper horizontal layers,
the additional insulating layer is in contact with an upper surface of the second region of the lowermost dummy upper horizontal layer, and
a side surface of the additional insulating layer is aligned with a side surface of the lowermost dummy upper horizontal layer.

9. The semiconductor device as claimed in claim 1, further comprising:
a lower structure; and
gate contact plugs,
wherein:
a memory cell region, a gate connection region, and a dummy region are defined on the lower structure,
the memory cell region is a region on which the gate stack region and the vertical memory structure are disposed,
the gate connection region is a region on which the gate layers extend from the memory cell region, and gate pads of the gate layers are arranged in a step shape,
the dummy region is a region on which the dummy stack region and the first vertical dummy structure are disposed,
the gate pads of the gate layers are in contact with the gate contact plugs, the gate connection region is disposed in a first direction of the memory cell region,
the dummy region is disposed in a second direction of the memory cell region, and
the second direction is perpendicular to the first direction.

10. The semiconductor device as claimed in claim 9, wherein:
a lower gate pad of the gate pads has a first thickness, and
at least one of upper gate pads at a higher level than the lower gate pad of the gate pads has a second thickness greater than the first thickness.

11. The semiconductor device as claimed in claim 9, wherein:
the lower structure includes a substrate, peripheral circuits on the substrate, and a pattern structure on the peripheral circuits,
the vertical memory structure and the first vertical dummy structure are in contact with the pattern structure,
the vertical memory structure includes:
an insulating core region in a channel hole penetrating through the gate stack region;
a channel layer covering at least a side surface of the insulating core region;
a data storage structure covering at least an outer side surface of the channel layer; and
a pad pattern on the insulating core region and in contact with the channel layer, and
the pattern structure includes a silicon layer penetrating through the data storage structure and in contact with the channel layer.

12. The semiconductor device as claimed in claim 1, further comprising:
a lower structure; and
an upper chip structure,
wherein:
the stack structure is on the lower structure,
the vertical memory structure and the first vertical dummy structure are in contact with the lower structure,
the upper chip structure further includes a substrate and peripheral circuits disposed below the substrate, and
the peripheral circuits are between the substrate and the stack structure.

13. A semiconductor device, comprising:
a lower structure including a memory cell region, a gate connection region, and a dummy region thereon;
a stack structure on each of the memory cell region, the gate connection region, and the dummy region on the lower structure;
a vertical memory structure penetrating through the stack structure on the memory cell region;
a vertical dummy structure penetrating through the stack structure on the dummy region; and
gate contact plugs on the gate connection region,
wherein:
the stack structure includes a gate stack region in each of the memory cell region and the gate connection region, and a dummy stack region in the dummy region,
the gate stack region includes a lower gate stack region and an upper gate stack region on the lower gate stack region,
the dummy stack region includes a dummy lower stack region and a dummy upper stack region on the dummy lower stack region,
the lower gate stack region includes lower interlayer insulating layers and lower gate layers alternately and repeatedly stacked on each other,
the upper gate stack region includes upper interlayer insulating layers and upper gate layers alternately and repeatedly stacked on each other,
the dummy lower stack region includes dummy lower insulating layers and dummy lower horizontal layers alternately stacked on each other,
the dummy upper stack region includes dummy upper insulating layers and dummy upper horizontal layers alternately stacked on each other,
the gate contact plugs are in contact with gate pads of the lower and upper gate layers in the gate connection region,
the gate connection region is disposed in a first direction of the memory cell region,
the dummy region is disposed in a second direction of the memory cell region,
the second direction is perpendicular to the first direction,
the vertical dummy structure is at a lower level than the dummy upper stack region, and
a lowermost dummy upper horizontal layer of the dummy upper horizontal layers overlaps an upper surface of the vertical dummy structure in the dummy region.

14. The semiconductor device as claimed in claim 13, further comprising:
a first lower insulating liner covering at least a portion of the lower gate stack region in the gate connection region;
a first upper insulating liner covering at least a portion of the upper gate stack region in the gate connection region;
a second lower insulating liner covering at least a portion of the dummy lower stack region in the dummy region; and
a second upper insulating liner covering at least a portion of the dummy upper stack region in the dummy region.

15. The semiconductor device as claimed in claim 14, wherein:
the first lower insulating liner does not vertically overlap the upper gate layers,
an upper end of the second lower insulating liner vertically overlaps the lowermost dummy upper horizontal layer, and
the first upper insulating liner has a side surface aligned with a side surface of a lowermost upper gate layer of the upper gate layers.

16. The semiconductor device as claimed in claim 14, wherein:
the first lower insulating liner vertically overlaps at least one of the upper gate layers,
an upper end of the second lower insulating liner vertically overlaps the lowermost dummy upper horizontal layer, and
the first upper insulating liner has a side surface aligned with a side surface of a lowermost upper gate layer of the upper gate layers.

17. The semiconductor device as claimed in claim 14, wherein an upper end of the second lower insulating liner is in contact with the lowermost dummy upper horizontal layer.

18. The semiconductor device as claimed in claim 14, further comprising an additional insulating layer in contact with a portion of an upper surface of the lowermost dummy upper horizontal layer,
wherein the second upper insulating liner is in contact with an upper surface of the additional insulating layer while covering the additional insulating layer.

19. A data storage system, comprising:
a semiconductor device including an input/output pad; and
a controller electrically connected to the semiconductor device through the input/output pad and controlling the semiconductor device,
wherein:
the semiconductor device includes a lower structure including a memory cell region, a gate connection region, and a dummy region thereon; a stack structure on each of the memory cell region, the gate connection region, and the dummy region on the lower structure; a vertical memory structure penetrating through the stack structure on the memory cell region; a vertical dummy structure penetrating through the stack structure on the dummy region; and gate contact plugs on the gate connection region,
the stack structure includes a gate stack region on each of the memory cell region and the gate connection region and a dummy stack region on the dummy region,
the gate stack region includes a lower gate stack region and an upper gate stack region on the lower gate stack region,
the dummy stack region includes a dummy lower stack region and a dummy upper stack region on the dummy lower stack region,
the lower gate stack region includes lower interlayer insulating layers and lower gate layers alternately and repeatedly stacked on each other,
the upper gate stack region includes upper interlayer insulating layers and upper gate layers alternately and repeatedly stacked on each other,
the dummy lower stack region includes dummy lower insulating layers and dummy lower horizontal layers alternately stacked on each other,
the dummy upper stack region includes dummy upper insulating layers and dummy upper horizontal layers alternately stacked on each other,
the gate contact plugs are in contact with gate pads of the lower and upper gate layers in the gate connection region,
the gate connection region is disposed in a first direction of the memory cell region,
the dummy region is disposed in a second direction of the memory cell region,
the second direction is perpendicular to the first direction,
the vertical dummy structure is at a lower level than the dummy upper stack region, and
a lowermost dummy upper horizontal layer of the dummy upper horizontal layers overlaps an upper surface of the vertical dummy structure in the dummy region.

20. The data storage system as claimed in claim 19, further comprising:
a first lower insulating liner covering at least a portion of the lower gate stack region in the gate connection region;
a first upper insulating liner covering at least a portion of the upper gate stack region in the gate connection region;
a second lower insulating liner covering at least a portion of the dummy lower stack region in the dummy region;
a second upper insulating liner covering at least a portion of the dummy upper stack region in the dummy region; and
an additional insulating layer in contact with a portion of an upper surface of the lowermost dummy upper horizontal layer,
wherein the second upper insulating liner is in contact with an upper surface of the additional insulating layer while covering the additional insulating layer.
